(19) United States
(12) Patent Application Publication
(10) Pub. No.: US 2012/0064713 A1
(43) Pub. Date: Mar. 15, 2012

(54) Ultra-low-k dual damascene structure and method of fabricating

(75) Inventors: Noel RUSSELL, Waterford, NY (US); Douglas M. TRICKETT, Altamont, NY (US); Kaushik Arun KUMAR, Poughkeepsie, NY (US)

(73) Assignee: TOKYO ELECTRON LIMITED, Tokyo (JP)

(21) Appl. No.: 12/879,745

(22) Filed: Sep. 10, 2010

(51) Int. Cl. H01L 21/768; H01L 21/311

(52) U.S. Cl. 438/653; 438/694; 257/E21.258; 257/E21.584

(57) ABSTRACT

A method of patterning an insulation layer is described. The method includes preparing a feature pattern in an insulation layer using at least one hard mask layer formed on the insulation layer, where the insulation layer contains a low-k material having a dielectric constant less than the dielectric constant of SiO₂. The method further includes removing the at least one hard mask layer to expose a flat field surface of the insulation layer and, following the removing, forming a passivation layer on the flat field surface to protect the insulation layer using gas cluster ion beam (GCIB) irradiation of the insulation layer, wherein the GCIB irradiation is configured to grow or deposit the passivation layer on the flat field surface.

### BACKGROUND OF THE INVENTION FIELD OF INVENTION

The invention relates to a method for patterning an insulation stack and, in particular, a method for treating exposed surfaces of a pattern formed in a low dielectric constant (low-k) insulation stack using gas cluster ion beam (GCIB) processing.

### DESCRIPTION OF RELATED ART

As is known to those in semiconductor device manufacturing, interconnect delay is a limiting factor in the drive to improve the speed and performance of integrated circuits (IC). One way to minimize interconnect delay is to reduce interconnect capacitance by using low dielectric constant (low-k) materials and ultra-low-k dielectric materials in metal interconnects during back-end-of-line (BEOL) operations for IC production. Such low-k materials presently include organosilicates, such as organosilicon glass or SiCOH-containing materials.

Thus, in recent years, low-k materials have been developed to replace relatively high dielectric constant insulating materials, such as silicon dioxide. In particular, low-k materials are being utilized for inter-level and intra-level dielectric layers between metal layers of semiconductor devices. Additionally, in order to further reduce the dielectric constant of insulating materials, material films are formed with pores, i.e., porous low-k dielectric materials. Such low-k materials can be deposited by a spin-on dielectric (SOD) method similar to the application of photoresist, or by chemical vapor deposition (CVD). Hence, the use of low-k materials is readily adaptable to existing semiconductor manufacturing processes.

When preparing a new interconnect level on a semiconductor substrate, a cap layer is typically formed overlying the preceding interconnect layer, followed by the formation of the low-k insulation layer and one or more layers, such as a hard mask, overlying the low-k insulation layer. Upon formation of the insulation stack, lithography and etch processing are utilized to pattern the insulation layers in preparation for subsequent metallization processes. For example, the insulation layer stack may be patterned with a trench-via structure according to various integration schemes, including dual damascene integration, when preparing a metal line and contact plug to provide electrical continuity between one interconnect layer and an adjacent interconnect layer.

However, the practical implementation of low-k materials in insulation layer stacks for metal interconnects faces formidable challenges. Ultimately, it is desirable to integrate low-k dielectric materials in metal interconnects that achieve the full benefit of the reduced dielectric constant, while producing a structurally robust, patterned insulation layer with minimal damage.

### SUMMARY OF THE INVENTION

The invention relates to a method for patterning an insulation stack and, in particular, a method for treating exposed surfaces of a pattern formed in a low dielectric constant (low-k) insulation stack using gas cluster ion beam (GCIB) processing.

According to one embodiment, a method of patterning an insulation layer is described. The method includes preparing a feature pattern in an insulation layer using at least one hard mask layer formed on the insulation layer, wherein the insulation layer comprises a low-k material having a dielectric constant less than the dielectric constant of SiO₂. The method further includes removing the at least one hard mask layer to expose a flat field surface of the insulation layer and, following the removing, forming a passivation layer on the flat field surface to protect the insulation layer using gas cluster ion beam (GCIB) irradiation of the insulation layer, wherein the GCIB irradiation is configured to grow or deposit the passivation layer on the flat field surface.

### BRIEF DESCRIPTION OF THE DRAWINGS

In the accompanying drawings:

FIGS. 1A through 1C illustrate, in schematic cross-sectional view a method of preparing an interconnect structure according to the prior art;

FIGS. 2A through 2J illustrate a schematic representation of a procedure for patterning an insulation layer according to an embodiment;

FIG. 3 provides a flow chart illustrating a method of patterning an insulation layer according to an embodiment;

FIGS. 4A through 4H illustrate a schematic representation of a procedure for preparing a trench-via structure on a substrate according to another embodiment;

FIGS. 5A through 5G illustrate a schematic representation of a procedure for preparing a trench-via structure on a substrate according to another embodiment;

FIG. 6 is an illustration of a gas cluster ion beam (GCIB) processing system;

FIG. 7 is another illustration of a GCIB processing system;

FIG. 8 is yet another illustration of a GCIB processing system;

FIG. 9 is an illustration of an ionization source for a GCIB processing system; and

FIG. 10 is another illustration of an ionization source for a GCIB processing system.

### DETAILED DESCRIPTION OF SEVERAL EMBODIMENTS

In the following description, for purposes of explanation and not limitation, specific details are set forth, such as a particular geometry of a processing system, descriptions of various components and processes used therein. However, it should be understood that the invention may be practiced in other embodiments that depart from these specific details.

Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

“Substrate” as used herein generically refers to the object being processed in accordance with the invention. The substrate may include any material portion or structure of a device, particularly a semiconductor or other electronics device, and may, for example, be a base substrate structure, such as a semiconductor wafer or a layer on or overlying a base substrate structure such as a thin film. Thus, substrate is not intended to be limited to any particular base structure, underlying layer or overlying layer, patterned or un-patterned, but rather, is contemplated to include any such layer or base structure, and any combination of layers and/or base structures. The description below may reference particular types of substrates, but this is for illustrative purposes only and not limitation.

As described above, it is desirable to integrate low-k dielectric materials in metal interconnects that achieve the full benefit of the reduced dielectric constant, while producing a structurally robust, patterned insulation layer with minimal damage. However, conventional integration schemes damage the low-k dielectric material during patterning of the insulation layer and result in a patterned interconnect structure that poses unfavorable conditions for subsequent metallization steps.

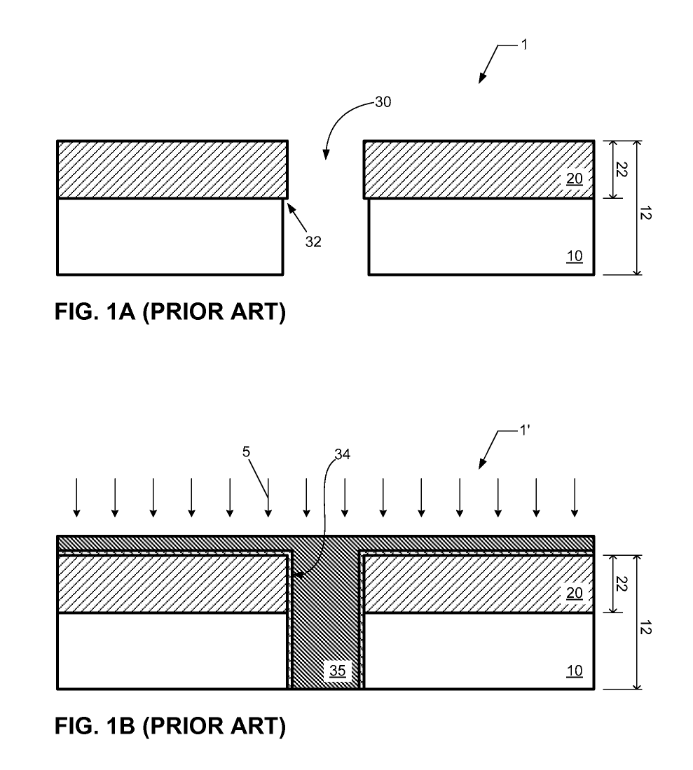

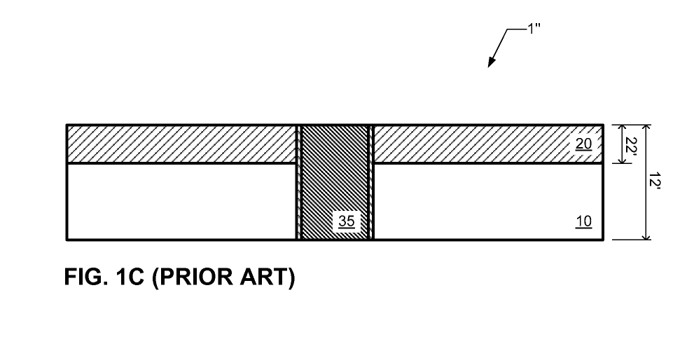

Referring now to FIGS. 1A through 1C, an interconnect structure of the prior art, in schematic cross-sectional view, is illustrated. A portion of an interconnect layer 1 is illustrated that includes a metal wiring layer with corresponding insulation layers prior to metallization. The interconnect layer 1 comprises a low dielectric constant (low-k) dielectric layer 10, a dielectric capping layer 20, and a feature pattern 30 formed therein which will subsequently be filled with metal. The low-k dielectric layer 10 may comprise a non-porous or porous, SiCOH-containing film, while the dielectric capping layer 20 may comprise SiO₂. The dielectric capping layer 20 may provide structural integrity to the insulation layers during ensuing process steps.

Conventionally, the low-k dielectric layer 10 and dielectric capping layer 20 are formed using vapor deposition techniques and the feature pattern 30 is prepared using a combination of lithographic and etch processes. These processes may damage the interface between the low-k dielectric layer 10 and dielectric capping layer 20 and, as illustrated in FIG. 1A, following patterning and cleaning an undercut 32 beneath the dielectric capping layer 20 may be observed. The undercut 32, as well as surface damage, e.g., moisture, contamination, etc., on exposed surfaces of the low-k dielectric layer 10 pose unfavorable conditions for subsequent metallization.

As shown in FIG. 1B, a metal barrier layer 34 and possibly a metal seed layer (not shown) are formed on the low-k dielectric layer 10 and dielectric capping layer 20, and then the feature pattern 30 is filled with metal to form metal line 35 in metalized interconnect layer 1′. The undercut 32, as well as the surface damage within the feature pattern 30, may cause poor adhesion of the metal barrier layer 34 to the low-k dielectric layer 10, voids in the metal barrier layer 34, voids in the metal line 35, among other things.

Following metallization, the metal filling the feature pattern 30 in the low-k dielectric layer 10 and the dielectric capping layer 20 is polished back until the dielectric capping layer 20 is reached. Moreover, the metal line 35 and the dielectric capping layer 20 are over-polished (labeled as “5” in FIG. 1B) to reduce the thickness of the dielectric capping layer 20. As shown in FIGS. 1A through 1C, an initial overall thickness 12 of the interconnect layer 1 (and metal line 35) is reduced to a final overall thickness 12′ of polished interconnect layer 1″ (and metal line 35) following the over-polishing step 5. Moreover, an initial thickness 22 of the dielectric capping layer 20 is reduced to a final thickness 22′ for the dielectric capping layer 20. Typically, the initial (22) and final (22′) thicknesses of the dielectric capping layer 20 occupy a substantial fraction of the initial (12) and final (12′) overall thicknesses of the metal line 35.

This limitation is due, in part, to the inability of conventional vapor deposition techniques to deposit thin films having a thickness less than about 10 nanometers (nm). As a result, the effective dielectric constant of the insulation layers (i.e., the low-k dielectric layer 10 and the dielectric capping layer 20) is compromised. For example, the initial overall thickness 12 of metal line 35 may be about 80 nm, and the final overall thickness 12′ may be about 50 nm. Further, for example, the initial thickness 22 of the dielectric capping layer 20 may be about 50 nm, and the final thickness 22′ may be about 20 nm. Consequently, the dielectric capping layer 20 (usually SiO₂ having a dielectric constant of 4) contributes up to about 40% of the effective dielectric constant for the insulation layers. Conventional techniques, including chemical vapor deposition (CVD) and chemical-mechanical planarization (CMP), cannot achieve film thicknesses less than about 10 nm for many insulation layers.

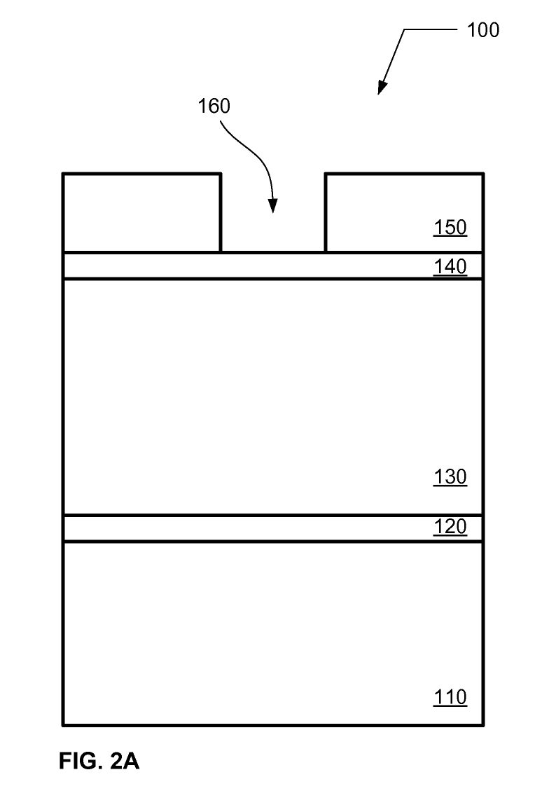

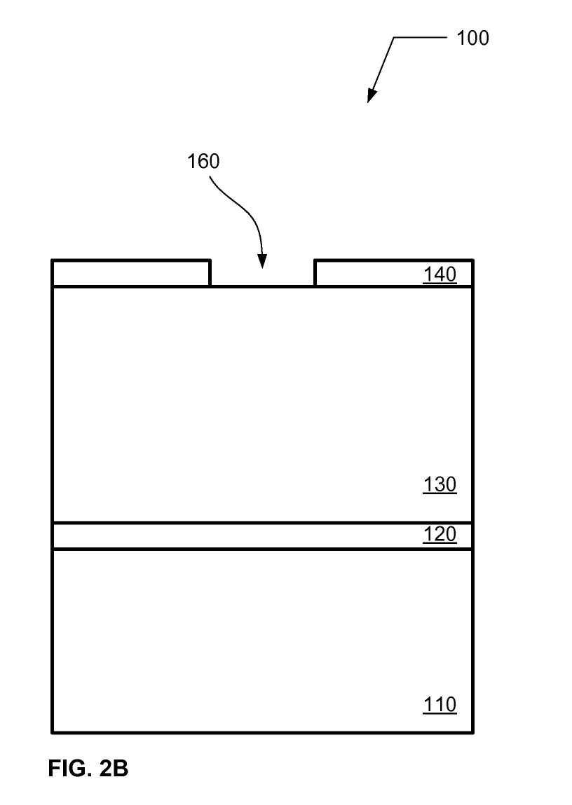

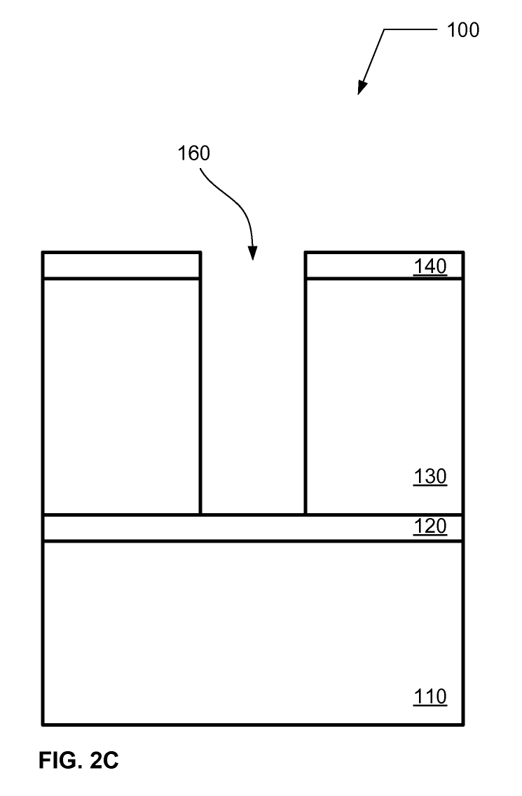

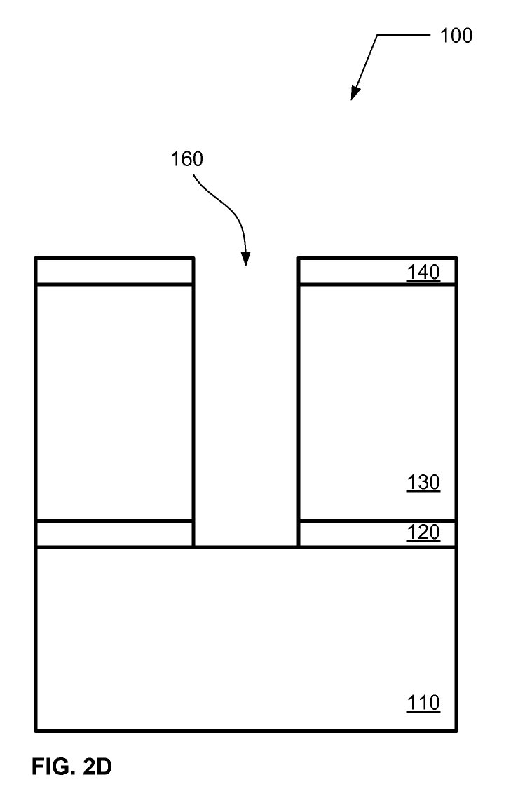

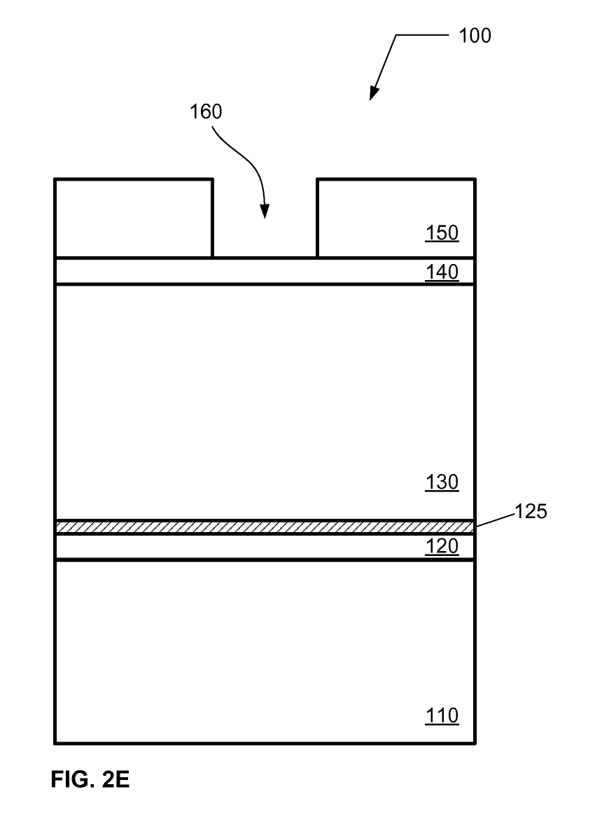

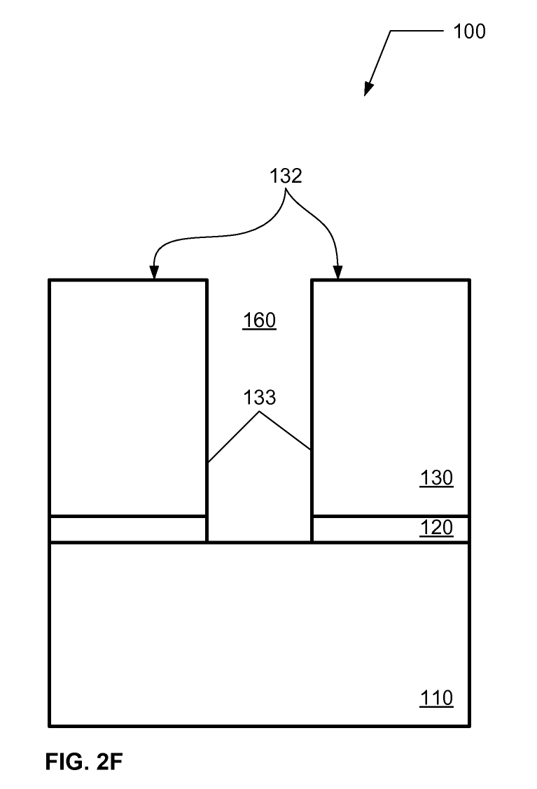

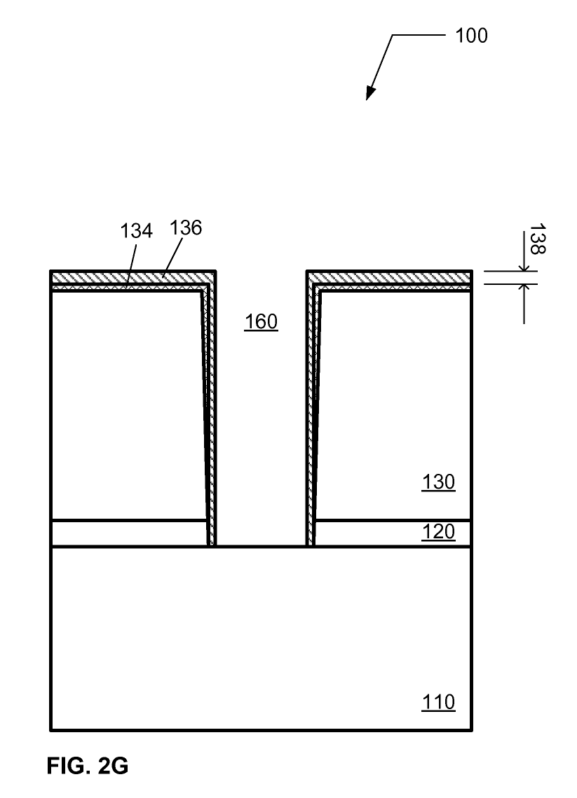

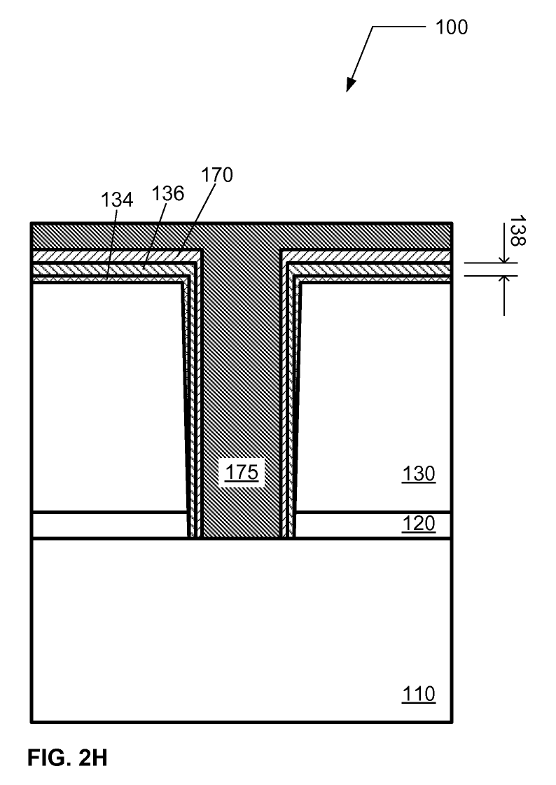

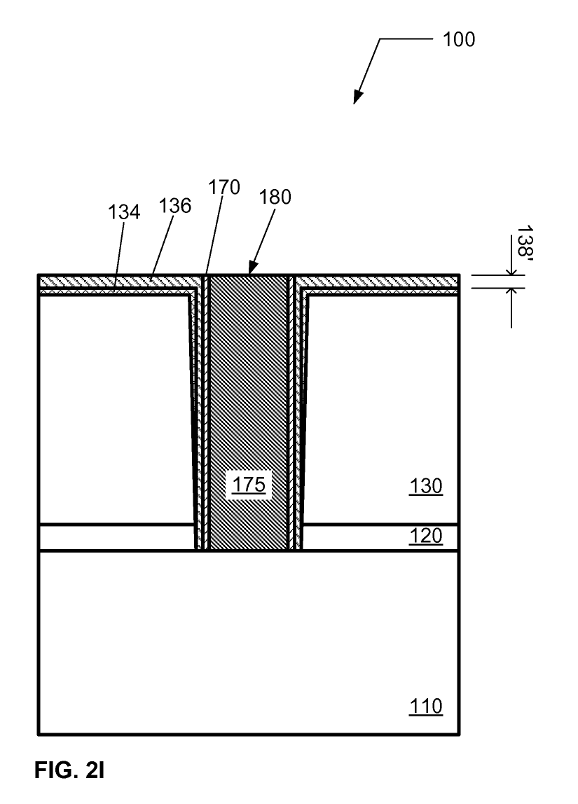

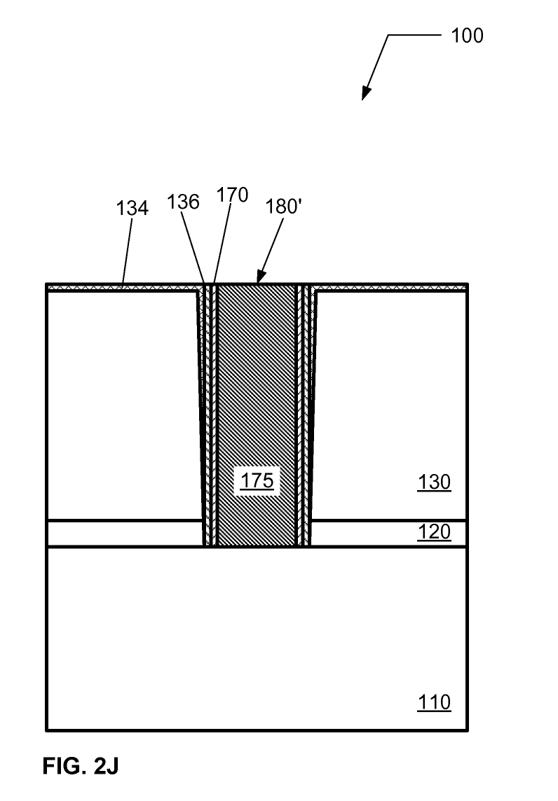

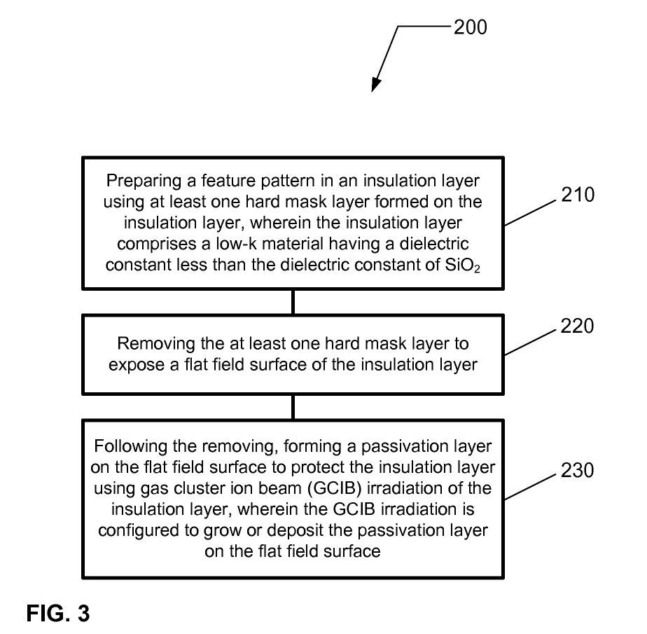

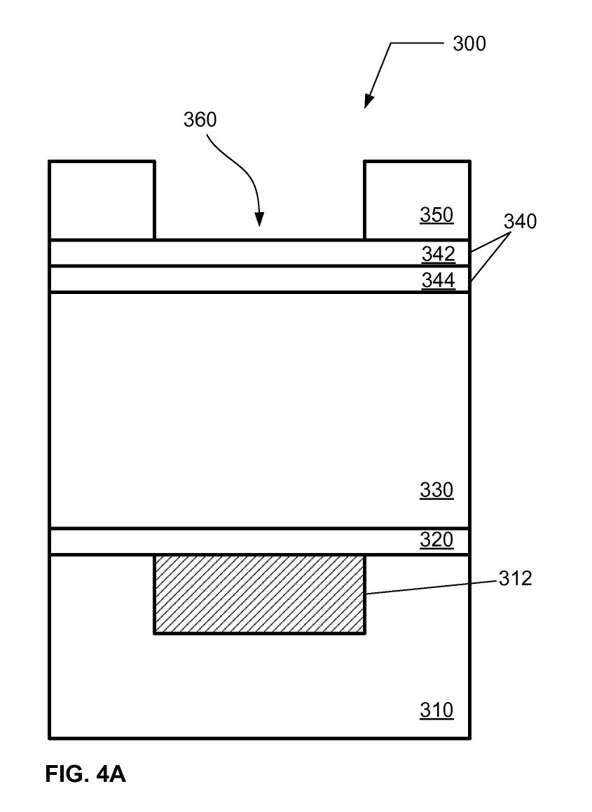

According to an embodiment, a method of patterning a structure on a substrate is schematically illustrated in FIGS. 2A through 2J, and is illustrated in a flow chart 200 in FIG. 3. For example, the structure may include a trench, a via, a contact, a hole, or other arbitrarily shaped structure. The method begins in 210 with preparing a feature pattern 160 in an insulation layer 130 using at least one hard mask layer 140 formed on the insulation layer 130, wherein the insulation layer 130 comprises a low-k material having a dielectric constant less than the dielectric constant of SiO₂. When preparing the feature pattern 160, a film stack 100 having a plurality of layers (i.e., layers 120 through 150) may be formed on a substrate 110. The film stack 100 comprises a cap layer 120, an insulation layer 130 overlying the cap layer 120, and the at least one hard mask layer 140 overlying the insulation layer 130. Additionally, the film stack 100 comprises a lithographic mask 150 formed on the at least one hard mask layer 140, wherein the feature pattern 160, such as a trench pattern, a via pattern, or a contact pattern, is initially formed using lithographic techniques. Although not shown, the film stack 100 may include additional layers.

The insulation layer 130 comprises a dielectric layer that may include a material layer, or plurality of material layers. For instance, the insulation layer 130 may include an organosilicate or organosilicon glass, such as a Si—O—C—H type material, or SiCOH-containing layer having silicon (Si), carbon (C), oxygen (O), and hydrogen (H). Moreover, the insulation layer 130 may comprise a low-k or ultra-low-k dielectric layer having Si, C, O, and optionally H, wherein a nominal dielectric constant value of the insulation layer 130 is less than the dielectric constant of SiO₂, which is approximately 4 (e.g., the dielectric constant for thermal silicon oxide can range from 3.8 to 3.9). More specifically, the insulation layer 130 may have a dielectric constant of less than 3.7, or a dielectric constant ranging from 1.6 to 3.7. The insulation layer 130 may be non-porous or porous.

The insulation layer 130 may be formed using a vapor deposition process, such as chemical vapor deposition (CVD), plasma enhanced CVD (PECVD), atomic layer deposition (ALD), plasma enhanced ALD (PEALD), physical vapor deposition (PVD), or ionized PVD (iPVD), or a spin-on technique, such as those offered in the CLEAN TRACK ACT 8 SOD (spin-on dielectric), ACT 12 SOD, and Lithius coating systems commercially available from Tokyo Electron Limited (TEL). The CLEAN TRACK ACT 8 (200 mm), ACT 12 (300 mm), and LITHIUS (300 mm) coating systems provide coat, bake, and cure tools for SOD materials. The track system can be configured for processing substrate sizes of 100 mm, 200 mm, 300 mm, and greater. Other systems and methods for forming a thin film on a substrate are well known to those skilled in the art of both spin-on technology and vapor deposition technology.

The cap layer 120 may include a single layer or multiple layers. For example, the cap layer 120 may include a nitrogen doped silicon carbide or Si—N—C—H. Furthermore, for example, the cap layer 120 may include silicon nitride (SiN_{y}), silicon carbide (SiC_{y}), silicon carbonitride (SiCₓN_{y}), or SiCₓN_{y}H_{z}, or a combination of two or more thereof. The cap layer 120 can be formed using a vapor deposition process, such as chemical vapor deposition (CVD), or plasma enhanced CVD (PECVD).

Optionally, as illustrated in FIG. 2E, the film stack 100 may further include a graded layer 125 disposed between the insulation layer 130 and the cap layer 120. The graded layer 125 may serve, among other things, to improve adhesion between the insulation layer 130 and the cap layer 120. For example, the graded layer 125 may include a layer containing Si and one or more elements selected from the group consisting of O, C, and N. The graded layer 125 can be formed using a vapor deposition process, such as chemical vapor deposition (CVD), or plasma enhanced CVD (PECVD). The CVD process may be tailored to grade or vary the composition of the graded layer 125 from top to bottom.

The at least one hard mask layer 140 may include a single layer or multiple layers. For example, the at least one hard mask layer 140 may include at least one layer containing Si, or at least one layer containing Si and O, or at least one layer containing a metal. Furthermore, for example, the at least one hard mask layer 140 may include a metal-containing layer, such as titanium (Ti), titanium nitride (TiN_{y}), tantalum (Ta), tantalum nitride (TaN_{y}), aluminum (Al), or aluminum-copper alloy (Al—Cu), or a dielectric material, such as silicon carbide (SiC_{y}), silicon oxide (SiO_{y}), silicon nitride (SiN_{y}), or silicon oxynitride (SiO_{y}N_{z}), or amorphous carbon (a-C). The at least one hard mask layer 140 can be formed using a vapor deposition process, such as chemical vapor deposition (CVD), or plasma enhanced CVD (PECVD).

The lithographic mask 150 may include one or more layers. For example, the lithographic mask 150 may comprise a layer of radiation-sensitive material, such as a light-sensitive material or photoresist, overlying an anti-reflective coating (ARC) layer. Additionally, for example, the lithographic mask 150 may comprise a layer of radiation-sensitive material overlying an ARC layer, which is overlying an optional organic planarization layer (OPL). Alternatively, the lithographic mask 150 may include a bi-layer mask, or multi-layer mask, having an ARC, such as a bottom ARC (BARC) layer, a sacrificial DUO™ layer, or a TERA (tunable etch-resistant ARC) layer, embedded therein.

The layer of radiation-sensitive material may comprise photoresist. For example, the layer of radiation-sensitive material may include 248 nm resists, 193 nm resists, 157 nm resists, EUV resists, or electron sensitive resists. The photoresist layer may be formed using spin-on techniques.

The ARC layer possesses material properties suitable for use as an anti-reflective coating. Additionally, the ARC layer is selected to be compatible with the overlying photoresist layer and the lithographic wavelength, i.e., ArF, KrF, etc. The ARC layer may be formed using vapor deposition techniques or spin-on techniques.

The optional OPL may include a photo-sensitive organic polymer or an etch type organic compound. For instance, the photo-sensitive organic polymer may be polyacrylate resin, epoxy resin, phenol resin, polyamide resin, polyimide resin, unsaturated polyester resin, polyphenylenether resin, polyphenylenesulfide resin, or benzocyclobutene (BCB). These materials may be formed using spin-on techniques.

One or more of the layers serving as lithographic mask 150 may be formed using a track system. For example, the track system may comprise a CLEAN TRACK ACT 8, ACT 12, or LITHIUS resist coating and developing system commercially available from Tokyo Electron Limited (TEL). Other systems and methods for forming a photoresist film on a substrate are well known to those skilled in the art of spin-on resist technology. The coating of the photoresist layer may include any or all processes known to those skilled in the art of preparing such films including, but not limited to, performing a cleaning process prior to the coating process, performing a post-application bake (PAB) following the coating process, etc.

As shown in FIG. 2A, feature pattern 160 is formed in the lithographic mask 150 using lithographic techniques. For example, the lithographic mask 150 may be imaged with an image pattern, and thereafter developed. The exposure to EM radiation is performed in a dry or wet photo-lithography system. The image pattern may be formed using any suitable conventional stepping lithographic system, or scanning lithographic system. For example, the photo-lithographic system may be commercially available from ASML Netherlands B.V. (De Run 6501, 5504 DR Veldhoven, The Netherlands), or Canon USA, Inc., Semiconductor Equipment Division (3300 North First Street, San Jose, Calif. 95134). If the lithographic mask 150 includes additional layers, such as an ARC layer, then feature pattern 160 may be transferred to these layers using dry development techniques and/or wet development techniques known to those skilled in the art of bi-layer, tri-layer, etc., mask development.

Thereafter, as shown in FIGS. 2B through 2D, the feature pattern 160 formed in lithographic mask 150 is transferred through the film stack 100 using a series of etch processes in a plasma etching system. The series of etch processes may utilize optimized etch processes with substrate temperature control schemes that achieve etch selectivity between the insulation layer 130 and the underlying cap layer 120.

As shown in FIG. 2B, feature pattern 160 is transferred through the at least one hard mask layer 140 using a first etch process. Optionally, feature pattern 160 may be partially transferred to the insulation layer 130 during the first etch process. The first etch process may include a dry etching process or a wet etching process. The etching process may include a dry plasma etching process or dry non-plasma etching process. When utilizing a dry plasma etching process, the plasma etch gas composition may include a halogen-containing chemistry. For example, the plasma etch gas composition may include Cl₂, BCl₃, Br₂, HBr, SF₆, or NF₃, or any combination of two or more thereof. Additionally, for example, the plasma etch gas composition may include a fluorocarbon-based chemistry such as at least one of C₄F₈, C₅F₈, C₃F₆, C₄F₆, CF₄, etc., or a fluorohydrocarbon-based chemistry such as at least one of CHF₃, CH₂F₂, etc., or a combination of two or more thereof. Furthermore, additive gases may include an inert gas, such as a noble gas, oxygen, hydrogen, nitrogen, CO₂, or CO, or two or more thereof. Alternatively, as would be understood by one skilled in the art of dry plasma etching, any etching process chemistry can be employed that selectively etches the at least one hard mask layer 140 relative to the lithographic mask 150.

Referring still to FIG. 2B, following the transfer of feature pattern 160 to the at least one hard mask layer 140, the lithographic mask 150 may be removed. However, it is not necessary that the lithographic mask 150 be removed. The lithographic mask 150 may be removed using a wet or dry stripping/ashing process.

As shown in FIG. 20, feature pattern 160 is transferred from the at least one hard mask layer 140 through the insulation layer 130 using a second etch process. The second etch process may include a dry etching process or a wet etching process. The etching process may include a dry plasma etching process or dry non-plasma etching process. When utilizing a dry plasma etching process, the plasma etch gas composition may include a halogen-containing chemistry. For example, the plasma etch gas composition may include Cl₂, BCl₃, Br₂, HBr, SF₆, or NF₃, or any combination of two or more thereof. Additionally, for example, the plasma etch gas composition may include a fluorocarbon-based chemistry such as at least one of C₄F₈, C₅F₈, C₃F₆, C₄F₆, CF₄, etc., or a fluorohydrocarbon-based chemistry such as at least one of CHF₃, CH₂F₂, etc., or a combination of two or more thereof. Furthermore, additive gases may include an inert gas, such as a noble gas, oxygen, hydrogen, nitrogen, CO₂, or CO, or two or more thereof. Alternatively, as would be understood by one skilled in the art of dry plasma etching, any etching process chemistry can be employed that selectively etches the insulation layer 130 relative to the other layers including the at least one hard mask layer 140 and the cap layer 120.

As shown in FIG. 2D, feature pattern 160 is transferred from the insulation layer 130 through the cap layer 120 using a third etch process. The third etch process may include a dry etching process or a wet etching process. The etching process may include a dry plasma etching process or dry non-plasma etching process. When utilizing a dry plasma etching process, the plasma etch gas composition may include a halogen-containing chemistry. For example, the plasma etch gas composition may include Cl₂, BCl₃, Br₂, HBr, SF₆, or NF₃, or any combination of two or more thereof. Additionally, for example, the plasma etch gas composition may include a fluorocarbon-based chemistry such as at least one of C₄F₈, C₅F₈, C₃F₆, C₄F₆, CF₄, etc., or a fluorohydrocarbon-based chemistry such as at least one of CHF₃, CH₂F₂, etc., or a combination of two or more thereof. Furthermore, additive gases may include an inert gas, such as a noble gas, oxygen, hydrogen, nitrogen, CO₂, or CO, or two or more thereof. Alternatively, as would be understood by one skilled in the art of dry plasma etching, any etching process chemistry can be employed that selectively etches the cap layer 120 relative to the other layers including the at least one hard mask layer 140 and the insulation layer 130.

As shown in FIG. 2F and FIG. 3, in 220, the at least one hard mask layer 140 is removed to expose a flat field surface 132 of the insulation layer 130. The removal process may include a polishing process, a planarization process, an etching process, a cleaning process, a dry etching process, a wet etching process, a dry plasma etching process, a dry non-plasma etching process, or a GCIB etching process, or any combination of two or more thereof.

Following the removal of the at least one hard mask layer 140, the exposed surfaces of the insulation layer 130 including the flat field surface 132 may be cleaned using a wet and/or dry cleaning process. The cleaning process may be used to remove contamination, moisture, etch process residue, ash process residue, etc. Additionally, the exposed surfaces of the insulation layer 130 including the flat field surface 132 may be treated to repair surface layers of the insulation layer 130. The treatment process may include performing at least one of healing damaged surfaces, sealing exposed porous surfaces, and cleaning damaged surfaces.

The healing process may include the rejuvenation of the insulation layer 130 by restoring the value of the dielectric constant. The restoration of the dielectric constant may, for example, be characterized by replenishing carbon depleted sites with carbon-containing material (e.g., CₓH_{y}, or CH₃, for example). The healing process may also include passivation of the insulation layer 130 using a treating agent that attacks the silanol (Si—OH) groups on the surface to the insulation layer 130 to form surface capped silyl groups that passivate the surface. Details of passivating an insulation layer are provided in U.S. patent application Ser. No. 10/682,196, filed Oct. 10, 2003, entitled “METHOD AND SYSTEM FOR TREATING A DIELECTRIC FILM”, and published as U.S. Patent Application Publication No. 2005/0077597A1, the entire content of which is incorporated herein by reference. Additionally, the sealing process can, for example, be characterized by the sealing of exposed pores in exposed surfaces. Furthermore, the cleaning process can include any one of removing moisture, removing contaminants or residue, etc.

As shown in FIG. 2G and FIG. 3, in 230, a passivation layer 136 is formed on the flat field surface 132 to protect the insulation layer 130 using gas cluster ion beam (GCIB) irradiation of the insulation layer 130, wherein the GCIB irradiation is configured to grow or deposit the passivation layer 136 on the flat field surface 132.

As illustrated in FIG. 2G, the passivation layer 136 may extend from the flat field surface 132 to at least a portion of a sidewall surface 133 of the feature pattern 160 in the insulation layer 130 using the GCIB irradiation, wherein a thickness of the passivation layer 136 on the portion of the sidewall surface is equal to or less than a thickness of the passivation layer 136 on the flat field surface 132, and wherein the passivation layer 136 is continuous from the flat field surface 132 to the portion of the sidewall surface.

Herein, the term “to form” (or “forming”, or “formation”) is used to broadly represent the preparation of a thin film of material on one or more surfaces of a substrate. Additionally herein, “growth” and “deposition” are defined and used in a manner to distinguish from one another. During growth, a thin film is formed on a substrate, wherein only a fraction of the atomic constituents of the thin film are introduced in the GCIB and the remaining fraction is provided by the substrate upon which the thin film is grown. For example, when growing SiOₓ on a substrate, the substrate may comprise a silicon surface, which is irradiated by a GCIB containing oxygen. The grown layer is thus a reaction product of the silicon from the silicon surface and the oxygen from the GCIB. To the contrary, during deposition, a thin film is formed on a substrate, wherein substantially all of the atomic constituents of the thin film are introduced in the GCIB. For example, when depositing SiCₓ, the substrate is irradiated by a GCIB containing both silicon and carbon.

As illustrated in FIG. 2G, during GCIB irradiation, material is infused within a sub-layer of the irradiated surface of insulation layer 130 at low GCIB dose, and may eventually transition to a purely deposition process at a higher GCIB dose. The infusion of material within the sub-layer forms a mixed layer 134, which acts as a graded interface between the underlying insulation layer 130 and passivation layer 136 subsequently grown or deposited on insulation layer 130. In part, the infused mixed layer 134 behaves as an adhesion layer. The material composition of the material infused in the insulation layer 130 to form the mixed layer 134 may be the same as the material composition of the material deposited to form passivation layer 136. Alternatively, the material composition of the material infused in insulation layer 130 to form the mixed layer 134 may be different than the material composition of the material deposited to form passivation layer 136.

In the former, where the material composition of the material infused in the insulation layer 130 to form the mixed layer 134 may be the same as the material composition of the material deposited to form passivation layer 136, one or more GCIBs may be used to form the passivation layer 136. In the latter, where the material composition of the material infused in insulation layer 130 to form the mixed layer 134 may be different than the material composition of the material deposited to form passivation layer 136, two or more GCIBs may be used to form the passivation layer 136, including both the mixed layer 134 and the passivation layer 136. Alternatively, in the latter, a conventional process may be used to form the mixed layer 134, followed by one or more GCIBs to form the passivation layer 136. The conventional process may include an implant process, a growth process, an oxidation process, a nitridation process, etc.

The passivation layer 136 may contain one or more elements selected from the group consisting of H, He, Ne, Ar, Xe, Kr, B, C, Si, Ge, N, P, As, O, S, F, CI, and Br. Further, the passivation layer 136 may contain one or more elements selected from the group consisting of Si, C, N, O, and H. For example, the passivation layer 136 may contain Si and one or more elements selected from the group consisting of C, N, O, and H. Additionally, for example, the passivation layer 136 may include SiOₓ, SiCₓ, SiNₓ, SiC_{X}N_{y}, etc. However, the passivation layer 136 may include other elements. Details for growing and depositing thin films are provided in U.S. patent application Ser. No. 12/144,968, filed Jun. 24, 2008, entitled “METHOD AND SYSTEM FOR GROWING A THIN FILM USING A GAS CLUSTER ION BEAM” (EP-118), and published as U.S. Patent Application Publication No. 2009/0317564A1; U.S. patent application Ser. No. 11/864,961, filed Sep. 29, 2007, entitled “METHOD FOR DEPOSITING FILMS USING A GAS CLUSTER ION BEAM PROCESSING” (EP-142), and published as U.S. Patent Application Publication No. 2009/0087578A1; U.S. patent application Ser. No. 12/399,449, filed Mar. 6, 2009, entitled “ULTRA-THIN FILM FORMATION USING A GAS CLUSTER ION BEAM PROCESSING” (EP-158); U.S. patent application Ser. No. 12/428,945, filed Apr. 23, 2009, entitled “MULTIPLE NOZZLE GAS CLUSTER ION BEAM SYSTEM” (EP-166); and U.S. patent application Ser. No. 12/428,973, filed Apr. 23, 2009, entitled “METHOD OF IRRADIATING SUBSTRATE WITH GAS CLUSTER ION BEAM FORMED FROM MULTIPLE GAS NOZZLES” (EP-172); the entire contents of which are incorporated herein by reference.

The inventors have discovered that high-quality, thin films may be formed using a growth and/or deposition process under various GCIB conditions. As will be described below, when growing a thin film, the inventors have observed that increasing the beam acceleration potential (or GCIB energy) can lead to thicker films for a given beam dose (or GCIB dose), while increasing the film roughness. Further, the inventors have observed that a GCIB growth process using relatively lower GCIB energy and/or broader GCIB energy distribution may be performed to achieve thin films, while achieving lower roughness. However, as will be discussed below, a broad range of GCIB energy, GCIB dose, and other parameters may be utilized to achieve thin films.

Additionally as will be described below, when depositing a thin film, the inventors have observed that increasing the GCIB energy can lead to thicker films for a given GCIB dose, while increasing the film roughness. Alternatively, the inventors have observed that a GCIB deposition process using relatively lower GCIB energy and/or broader GCIB energy distribution may be performed to achieve thin films, while achieving lower roughness. However, a broad range of GCIB energy and GCIB dose, including other parameters as will be discussed below, may be utilized to achieve thin films. Furthermore as will be discussed below, a pre-treatment process and/or post-treatment process may be performed to adjust one or more film properties including, but not limited to, a film thickness, a film roughness, a film adhesion, a film composition, etc.

According to an embodiment, a method of forming passivation layer 136 on a substrate is described. The method comprises: providing a substrate in a reduced-pressure environment; establishing a GCIB; selecting a beam energy, a beam energy distribution, a beam focus, and a beam dose to achieve a desired thickness of the passivation layer 136 formed during the GCIB irradiation of the insulation layer 130; accelerating the GCIB to achieve the beam energy; focusing the GCIB to achieve the beam focus; and exposing the insulation layer 130 to the accelerated GCIB according to the beam dose, wherein the beam energy ranges from about 1 keV to about 60 keV, and the beam dose ranges from about 1×10¹² clusters per cm² to about 1×10¹⁴ clusters per cm².

Herein, beam dose is given the units of number of clusters per unit area. However, beam dose may also include beam current and/or time (e.g., GCIB dwell time). For example, the beam current may be measured and maintained constant, while time is varied to change the beam dose. Alternatively, for example, the rate at which clusters strike the surface of the substrate per unit area (i.e., number of clusters per unit area per unit time) may be held constant while the time is varied to change the beam dose.

Additionally, other GCIB properties may be varied to adjust the film thickness, and other film properties such as the surface roughness, including, but not limited to, gas flow rate, stagnation pressure, cluster size, or gas nozzle design (such as nozzle throat diameter, nozzle length, and/or nozzle divergent section half-angle). Furthermore, other film properties may be varied by adjusting the GCIB properties including, but not limited to, film density, film quality, etc.

The passivation layer 136 may be grown or deposited to achieve a thickness 138 up to about 25 nm (nanometers). Alternatively, the passivation layer 136 is formed to a thickness 138 up to about 10 nm. Alternatively yet, the passivation layer 136 is formed to a thickness 138 ranging from about 2 nm to about 5 nm.

Either preceding the forming of the passivation layer 136 or following the forming the passivation layer 136, the insulation layer 130 may be subjected to another GCIB irradiation. The another GCIB irradiation may include another GCIB containing at least one element selected from the group consisting of He, Ne, Ar, Xe, Kr, B, C, Si, Ge, N, P, As, O, S, F, Cl, and Br. For example, the another GCIB may be used to smooth, amorphize, densify, etch, deposit, grow, infuse, an/or dope surface layers on the insulation layer 130.

As illustrated in FIG. 2H, a metal barrier layer 170 is formed on the passivation layer 136 and the insulation layer 130 conformal with the feature pattern 160, the feature pattern 160 is filled with metal 175. Thereafter, the metal 175 is polished to produce an upper metal surface 180 coplanar with the flat field surface 132 of the insulation layer 130 or at least a portion of the passivation layer 136 on the flat field surface 132 of the insulation layer 130. As illustrated in FIG. 2I, the metal 175 may be polished to consume part of passivation layer 136 to a thickness 138′ or, as illustrated in FIG. 2J, the metal 175 may be polished to consume substantially all of passivation layer 136 and form upper metal surface 180′.

In one embodiment, the processes described above for patterning film stack 100 in FIGS. 1A through 1J, and FIG. 2, may be utilized within a damascene integration scheme, or a dual damascene integration scheme. For example, the processes described above for patterning film stack 100 may be utilized within a trench-first-metal-hard-mask (TFMHM) integration scheme for dual damascene metal interconnect fabrication. Alternatively, for example, the processes described above for patterning film stack 100 may be utilized within a via-first-trench-last (VFTL) integration scheme for dual damascene metal interconnect fabrication.

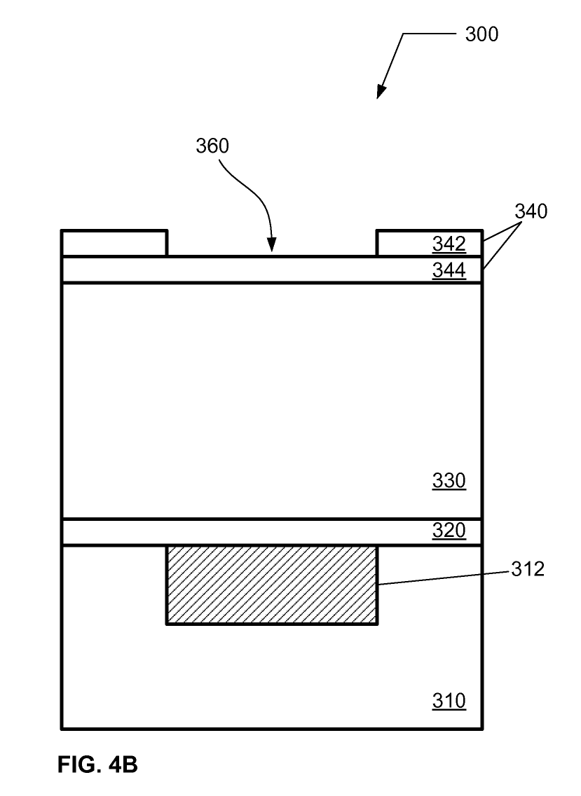

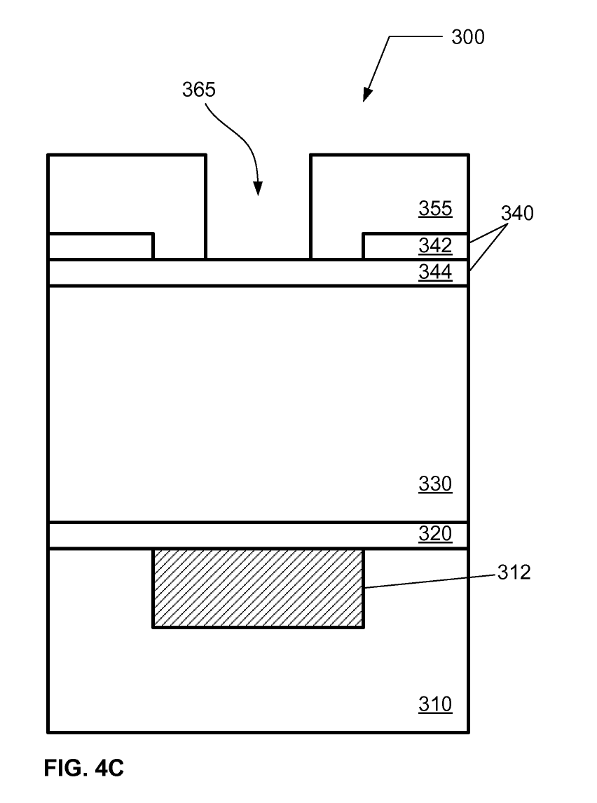

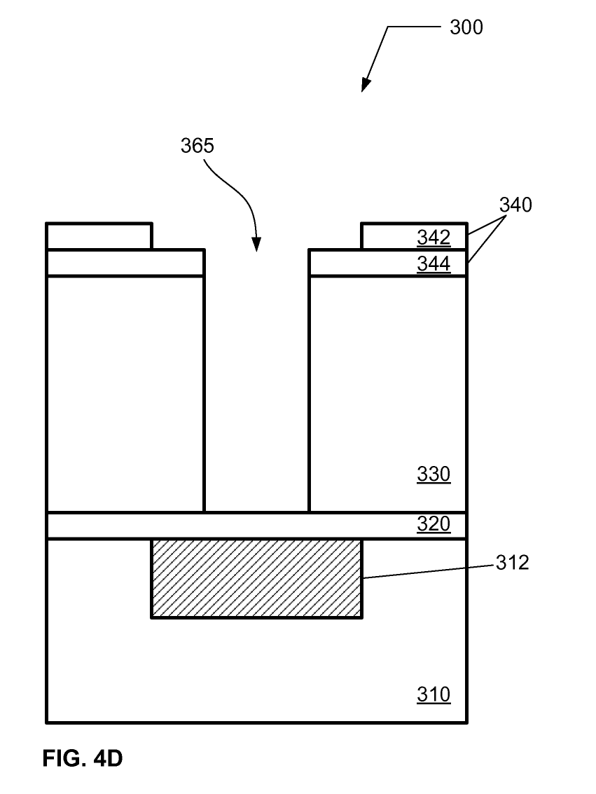

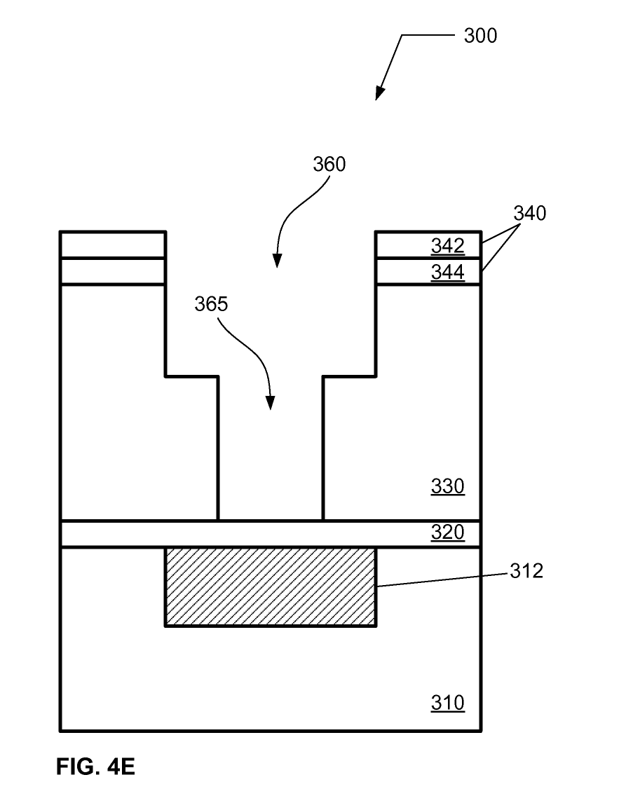

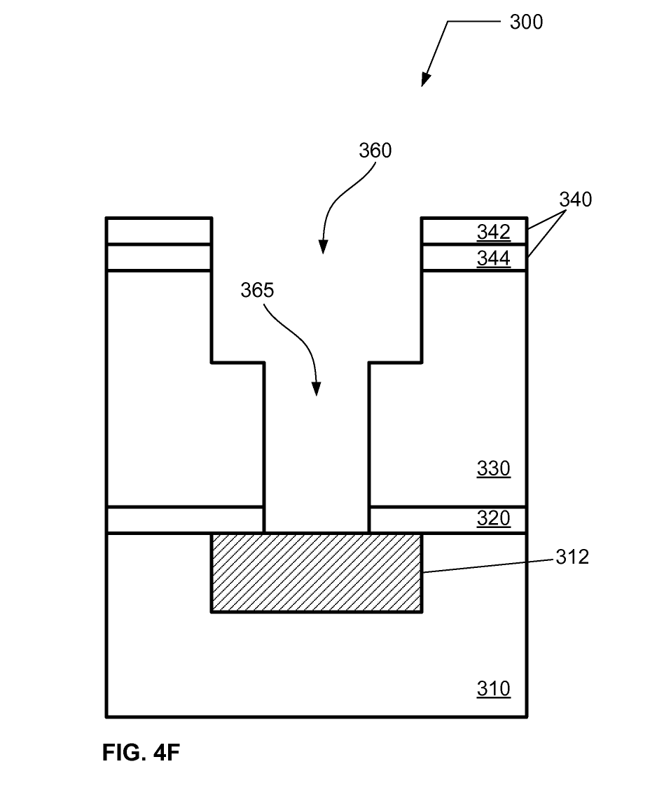

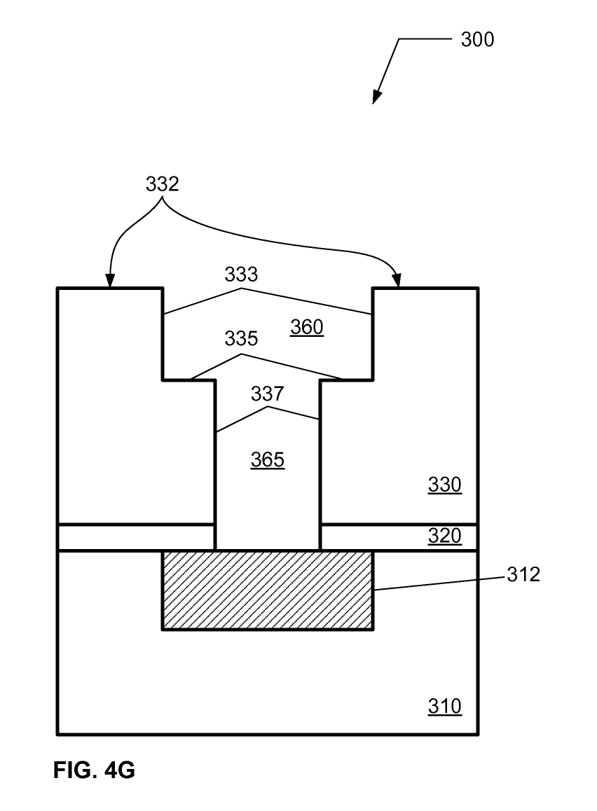

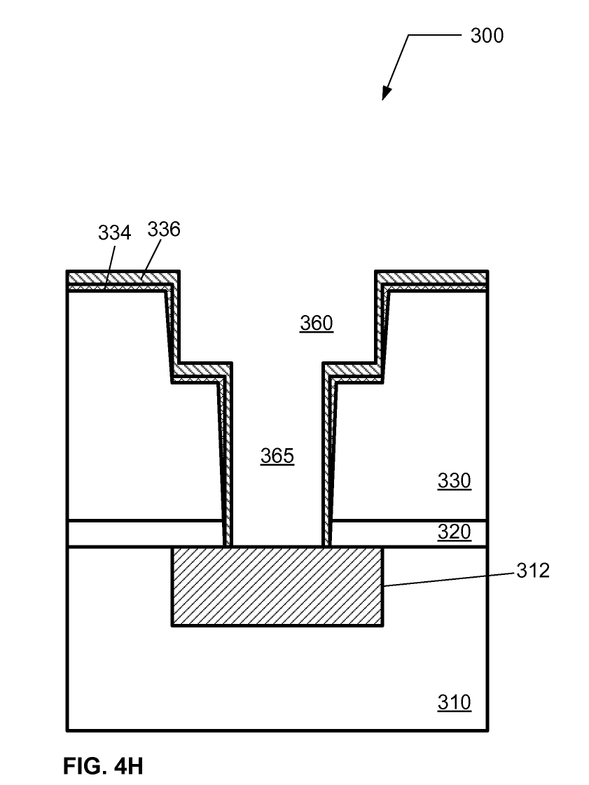

Referring now to FIGS. 4A through 4F, a method of preparing a trench-via structure on a substrate is illustrated according to an embodiment. The method for preparing the trench-via structure may include a trench-first-metal-hard-mask (TFMHM) integration scheme for dual damascene metal interconnect fabrication. As shown in FIGS. 4A through 4F, the trench-via structure is formed through a film stack 300. Thereafter, the trench-via structure is lined with one or more conformal thin films, wherein the one or more conformal thin films include a metal barrier layer, a metal adhesion layer, or a metal seed layer, or any combination of two or more thereof. After the liner is formed, the trench-via structure is filled with metal, such as Cu, and planarized using, for example, chemical-mechanical planarization (CMP) to form a metal interconnect and achieve electrical contact to a metal line 312 in substrate 310.

Referring to FIG. 4A, the film stack 300 is formed on substrate 310, wherein the film stack 300 comprises a cap layer 320, an insulation layer 330 overlying the cap layer 320, and at least one hard mask layer 340 overlying the insulation layer 330. As discussed above, the at least one hard mask layer 340 may include multiple layers, such as a metal hard mask layer 342 and a silicon-containing layer 344.

Using lithographic techniques, a first mask 350 (or trench patterning layer) is prepared having a trench pattern 360 formed therein. As shown in FIG. 4B, the trench pattern 360 in the first mask 350 is transferred to the metal hard mask layer 342 via an etching process, and the first mask 350 is removed.

Referring to FIG. 4C, a second mask 355 (or via patterning layer) is prepared having a via pattern 365 formed therein. The via pattern 365 is aligned with the trench pattern 360. As shown in FIG. 4D, the via pattern 365 is at least partially transferred from the second mask 355 to the insulation layer 330 using a first etch process in the plasma etching system. Thereafter, the second mask 355 is removed.

Referring to FIG. 4E, the trench pattern 360 in the metal hard mask layer 342 is transferred to silicon-containing layer 344 and the insulation layer 330 using a second etch process in the plasma etching system while not penetrating the cap layer 320.

Then, referring to FIG. 4F, the via pattern 365 in the insulation layer 330 is transferred to the cap layer 320 using a third etch process in the plasma etching system. During the series of etch processes, i.e., the first etch process, the second etch process, and the third etch process, a temperature controlled substrate holder may be utilized in the plasma etching system according to a substrate temperature control scheme to achieve etch selectivity between the insulation layer 330 and the cap layer 320 during the transferring of the trench pattern 360.

The substrate temperature control scheme may include: controlling a first substrate temperature in the first etch process step for transferring the via pattern 365 at least partially into the insulation layer 330, controlling a second substrate temperature at a temperature greater than the first substrate temperature in the second etch process step for transferring the trench pattern 360 to the insulation layer 330, and controlling a third substrate temperature at a temperature less than the second substrate temperature in the third etch process step for transferring the via pattern 365 to the cap layer 320.

Referring to FIG. 4G, the at least one hard mask layer 340, including metal hard mask layer 342 and silicon-containing layer 344, is removed to expose a flat field surface 332 of the insulation layer 330. The removal process may include a polishing process, a planarization process, an etching process, a cleaning process, a dry etching process, a wet etching process, a dry plasma etching process, a dry non-plasma etching process, or a GCIB etching process, or any combination of two or more thereof.

Following the removal of the at least one hard mask layer 340, the exposed surfaces of the insulation layer 330 including the flat field surface 332 may be cleaned using a wet and/or dry cleaning process. Additionally, the exposed surfaces of the insulation layer 330 including the flat field surface 332 may be treated to repair surface layers of the insulation layer 330. The exposed surfaces may further include trench sidewalls 333, trench bottom 335, and via sidewalls 337. As described above, the treatment process may include performing at least one of healing damaged surfaces, sealing exposed porous surfaces, and cleaning damaged surfaces.

As shown in FIG. 4H, a passivation layer 336 is formed on the flat field surface 332 to protect the insulation layer 330 using gas cluster ion beam (GCIB) irradiation of the insulation layer 330, wherein the GCIB irradiation is configured to grow or deposit the passivation layer 336 on the flat field surface 332.

As illustrated in FIG. 4H, the passivation layer 336 may extend from the flat field surface 332 to at least a portion of a sidewall surface of the trench pattern 360 in the insulation layer 330 using the GCIB irradiation, wherein a thickness of the passivation layer 336 on the portion of the sidewall surface is equal to or less than a thickness of the passivation layer 336 on the flat field surface 332, and wherein the passivation layer 336 is continuous from the flat field surface 332 to the portion of the sidewall surface. For example, the passivation layer 336 may extend onto trench sidewalls 333, trench bottom 335, and via sidewalls 337.

As illustrated in FIG. 4H, during GCIB irradiation, material is infused within a sub-layer of the irradiated surface of insulation layer 330 at low GCIB dose, and may eventually transition to a purely deposition process at a higher GCIB dose. The infusion of material within the sub-layer forms a mixed layer 334, which acts as a graded interface between the underlying insulation layer 330 and passivation layer 336 subsequently grown or deposited on insulation layer 330. In part, the infused mixed layer 334 behaves as an adhesion layer. The material composition of the material infused in the insulation layer 330 to form the mixed layer 334 may be the same as the material composition of the material deposited to form passivation layer 336. Alternatively, the material composition of the material infused in insulation layer 330 to form the mixed layer 334 may be different than the material composition of the material deposited to form passivation layer 336.

In the former, where the material composition of the material infused in the insulation layer 330 to form the mixed layer 334 may be the same as the material composition of the material deposited to form passivation layer 336, one or more GCIBs may be used to form the passivation layer 336. In the latter, where the material composition of the material infused in insulation layer 330 to form the mixed layer 334 may be different than the material composition of the material deposited to form passivation layer 336, two or more GCIBs may be used to form the passivation layer 336, including both the mixed layer 334 and the passivation layer 336. Alternatively, in the latter, a conventional process may be used to form the mixed layer 334, followed by one or more GCIBs to form the passivation layer 336. The conventional process may include an implant process, a growth process, an oxidation process, a nitridation process, etc.

The trench-via structure, including trench 360 and via 365, may then be lined with one or more conformal thin films, wherein the one or more conformal thin films include a metal barrier layer, a metal adhesion layer, or a metal seed layer, or any combination of two or more thereof. After the liner is formed, the trench-via structure is filled with metal, such as Cu, and planarized to produce a metal interconnect with an upper surface coplanar with an upper surface of passivation layer 336, a surface at an intermediate depth within passivation layer 336, or an upper surface of mixed layer 334.

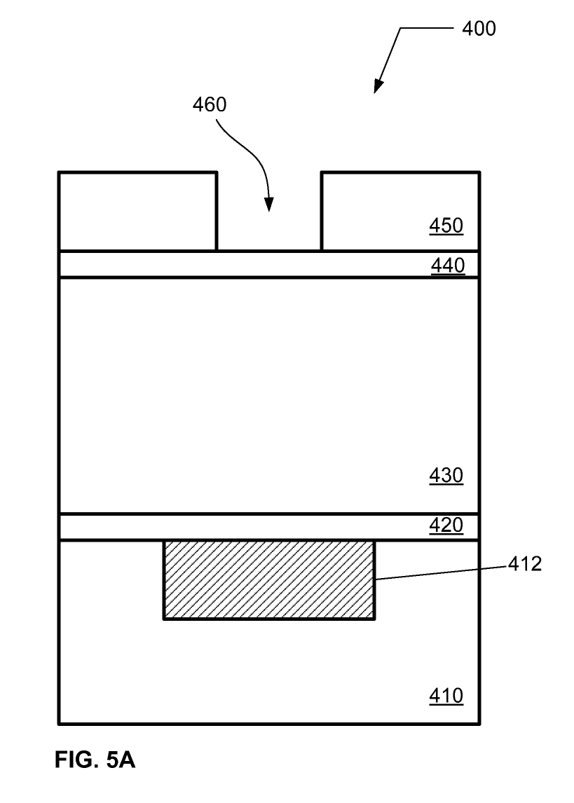

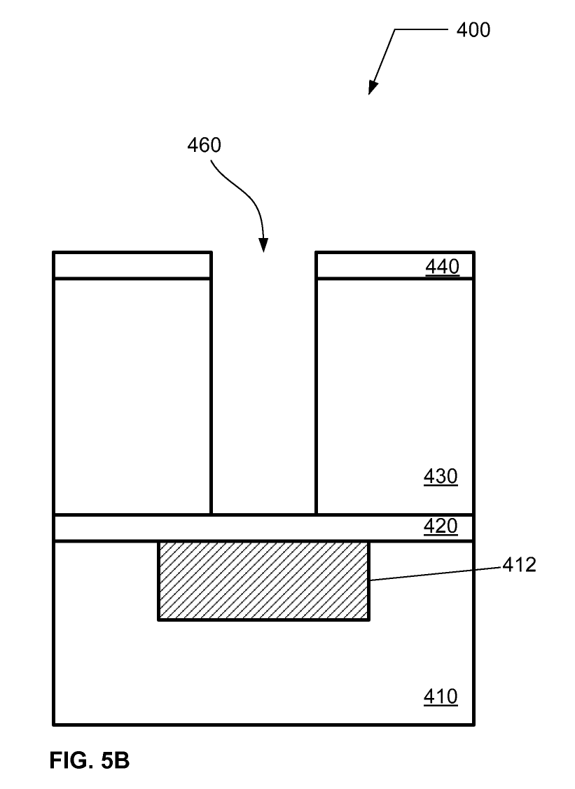

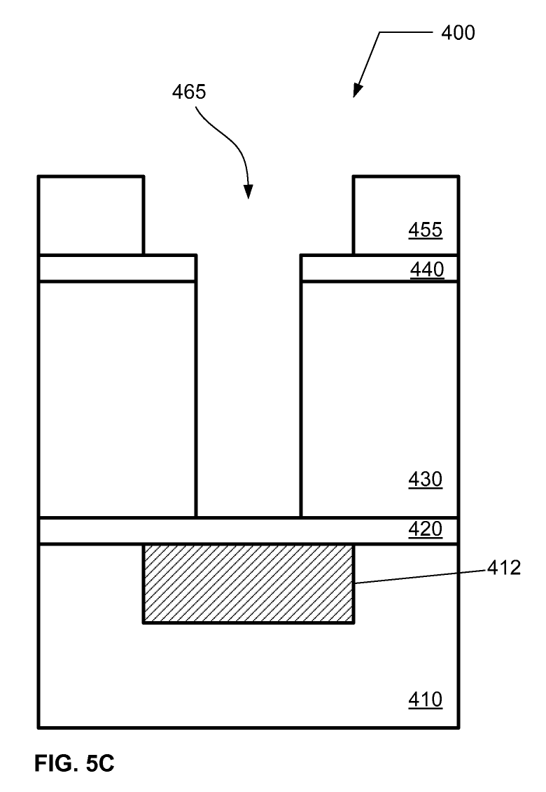

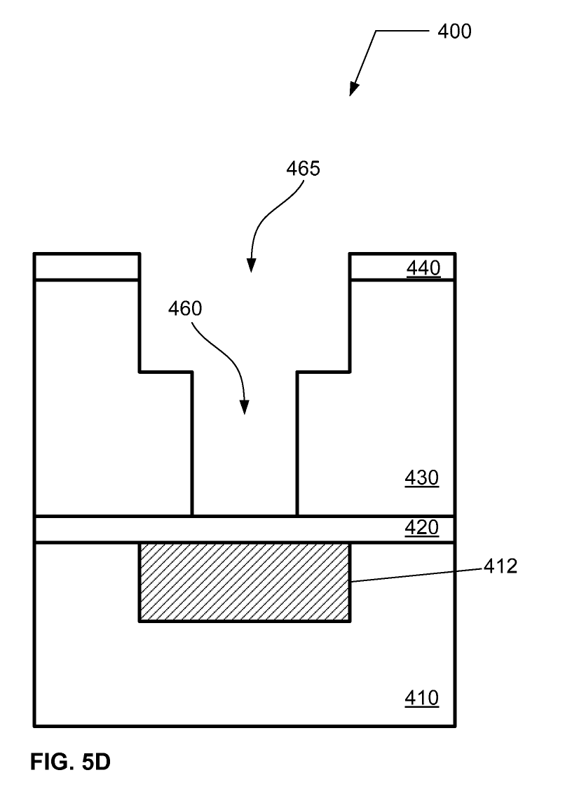

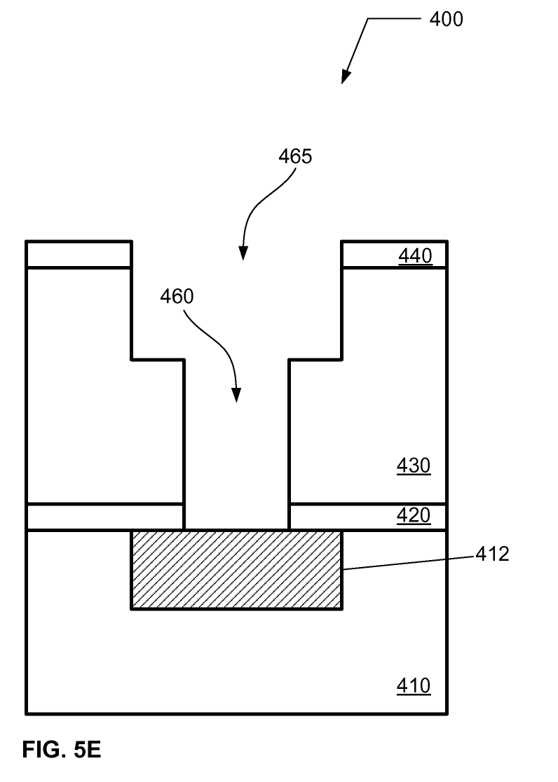

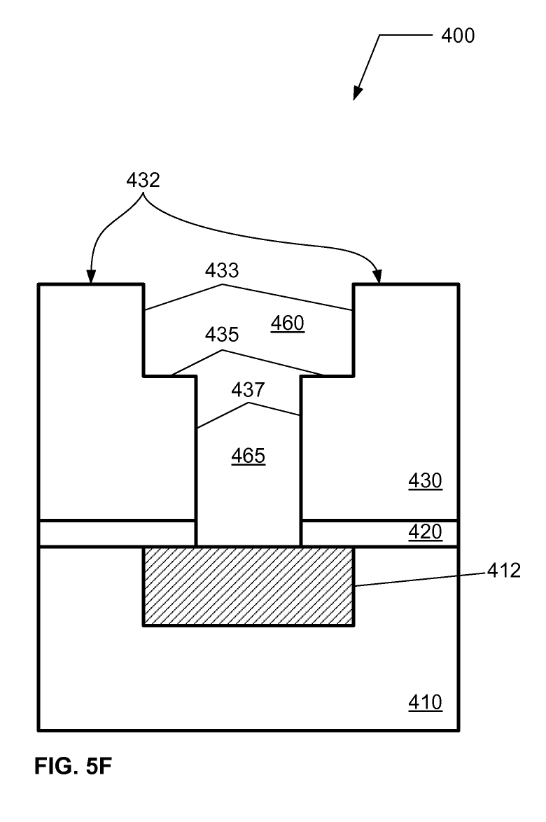

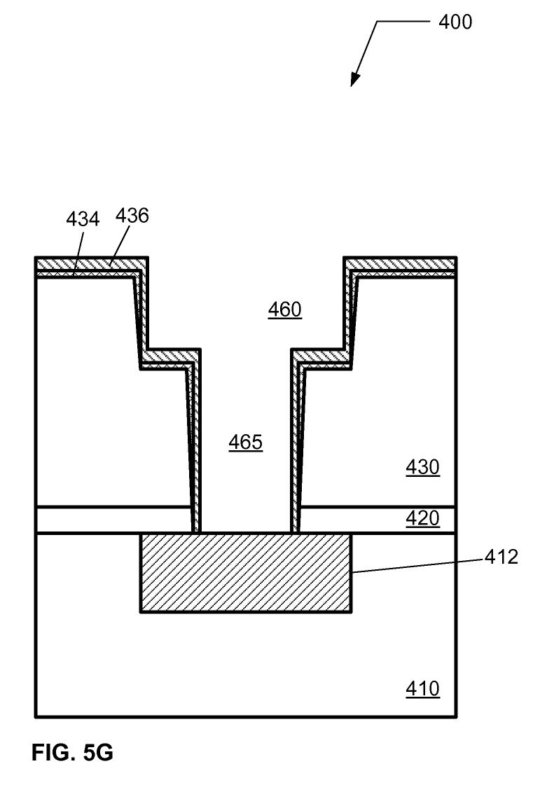

Referring now to FIGS. 5A through 5E, a method of preparing a trench-via structure on a substrate is illustrated according to an embodiment. The method for preparing the trench-via structure may include a via-first-trench-last (VFTL) integration scheme for dual damascene metal interconnect fabrication. As shown in FIGS. 5A through 5E, the trench-via structure is formed through a film stack 400. Thereafter, the trench-via structure is lined with one or more conformal thin films, wherein the one or more conformal thin films include a metal barrier layer, a metal adhesion layer, or a metal seed layer, or any combination of two or more thereof. After the liner is formed, the trench-via structure is filled with metal, such as Cu, and planarized using, for example, chemical-mechanical planarization (CMP) to form a metal interconnect and achieve electrical contact to a metal line 412 in substrate 410.

Referring to FIG. 5A, the film stack 400 is formed on substrate 410, wherein the film stack 400 comprises a cap layer 420, an insulation layer 430 overlying the cap layer 420, and at least one hard mask layer 440 overlying the insulation layer 430.

Using lithographic techniques, a first mask 450 (or via patterning layer) is prepared having a via pattern 460 formed therein. As shown in FIG. 5B, the via pattern 460 in the first mask 450 is transferred to the at least one hard mask layer 440 via an etching process, and the first mask 450 is removed.

Referring still to FIG. 5B, the via pattern 460 in the at least one hard mask layer 440 is at least partially transferred to the insulation layer 430 using a first etch process in the plasma etching system, and the first mask 450 is removed.

Referring to FIG. 5C, a second mask 455 (or trench patterning layer) is prepared having a trench pattern 465 formed therein. The trench pattern 465 is aligned with the via pattern 460. As shown in FIG. 5D, the trench pattern 465 is transferred from the second mask 455 to the at least one hard mask layer 440, and the second mask 455 is removed.

Referring to FIG. 5D, the trench pattern 465 in at least one hard mask layer 440 is transferred to the insulation layer 430 using a second etch process in the plasma etching system while not penetrating the cap layer 420.

Then, referring to FIG. 5E, the via pattern 460 in the insulation layer 430 is transferred to the cap layer 420 using a third etch process in the plasma etching system. During the series of etch processes, i.e., the first etch process, the second etch process, and the third etch process, a temperature controlled substrate holder is utilized in the plasma etching system according to a substrate temperature control scheme to achieve etch selectivity between the insulation layer 430 and the cap layer 420 during the transferring of the trench pattern 465.

The substrate temperature control scheme includes: controlling a first substrate temperature in the first etch process for transferring the via pattern 460 at least partially to the insulation layer 430, controlling a second substrate temperature at a temperature greater than the first substrate temperature in the second etch process for transferring the trench pattern 465 to the insulation layer 430, and controlling a third substrate temperature at a temperature less than the second substrate temperature in the third etch process for transferring the via pattern 460 to the cap layer 420.

Referring to FIG. 5F, the at least one hard mask layer 440 is removed to expose a flat field surface 432 of the insulation layer 430. The removal process may include a polishing process, a planarization process, an etching process, a cleaning process, a dry etching process, a wet etching process, a dry plasma etching process, a dry non-plasma etching process, or a GCIB etching process, or any combination of two or more thereof.

Following the removal of the at least one hard mask layer 440, the exposed surfaces of the insulation layer 430 including the flat field surface 432 may be cleaned using a wet and/or dry cleaning process. Additionally, the exposed surfaces of the insulation layer 430 including the flat field surface 432 may be treated to repair surface layers of the insulation layer 430. The exposed surfaces may further include trench sidewalls 433, trench bottom 435, and via sidewalls 437. As described above, the treatment process may include performing at least one of healing damaged surfaces, sealing exposed porous surfaces, and cleaning damaged surfaces.

As shown in FIG. 5G, a passivation layer 436 is formed on the flat field surface 432 to protect the insulation layer 430 using gas cluster ion beam (GCIB) irradiation of the insulation layer 430, wherein the GCIB irradiation is configured to grow or deposit the passivation layer 436 on the flat field surface 432.

As illustrated in FIG. 5G, the passivation layer 436 may extend from the flat field surface 432 to at least a portion of a sidewall surface of the via pattern 460 in the insulation layer 430 using the GCIB irradiation, wherein a thickness of the passivation layer 436 on the portion of the sidewall surface is equal to or less than a thickness of the passivation layer 436 on the flat field surface 432, and wherein the passivation layer 436 is continuous from the flat field surface 432 to the portion of the sidewall surface. For example, the passivation layer 436 may extend onto trench sidewalls 433, trench bottom 435, and via sidewalls 437.

As illustrated in FIG. 5G, during GCIB irradiation, material is infused within a sub-layer of the irradiated surface of insulation layer 430 at low GCIB dose, and may eventually transition to a purely deposition process at a higher GCIB dose. The infusion of material within the sub-layer forms a mixed layer 434, which acts as a graded interface between the underlying insulation layer 430 and passivation layer 436 subsequently grown or deposited on insulation layer 430. In part, the infused mixed layer 434 behaves as a diffusion barrier. The material composition of the material infused in the insulation layer 430 to form the mixed layer 434 may be the same as the material composition of the material deposited to form passivation layer 436. Alternatively, the material composition of the material infused in insulation layer 430 to form the mixed layer 434 may be different than the material composition of the material deposited to form passivation layer 436.

In the former, where the material composition of the material infused in the insulation layer 430 to form the mixed layer 434 may be the same as the material composition of the material deposited to form passivation layer 436, one or more GCIBs may be used to form the passivation layer 436. In the latter, where the material composition of the material infused in insulation layer 430 to form the mixed layer 434 may be different than the material composition of the material deposited to form passivation layer 436, two or more GCIBs may be used to form the passivation layer 436, including both the mixed layer 434 and the passivation layer 436. Alternatively, in the latter, a conventional process may be used to form the mixed layer 434, followed by one or more GCIBs to form the passivation layer 436. The conventional process may include an implant process, a growth process, an oxidation process, a nitridation process, etc.

The trench-via structure, including via pattern 460 and trench 465, may then be lined with one or more conformal thin films, wherein the one or more conformal thin films include a metal barrier layer, a metal adhesion layer, or a metal seed layer, or any combination of two or more thereof. After the liner is formed, the trench-via structure is filled with metal, such as Cu, and planarized to produce a metal interconnect with an upper surface coplanar with an upper surface of passivation layer 436, a surface at an intermediate depth within passivation layer 436, or an upper surface of mixed layer 434.

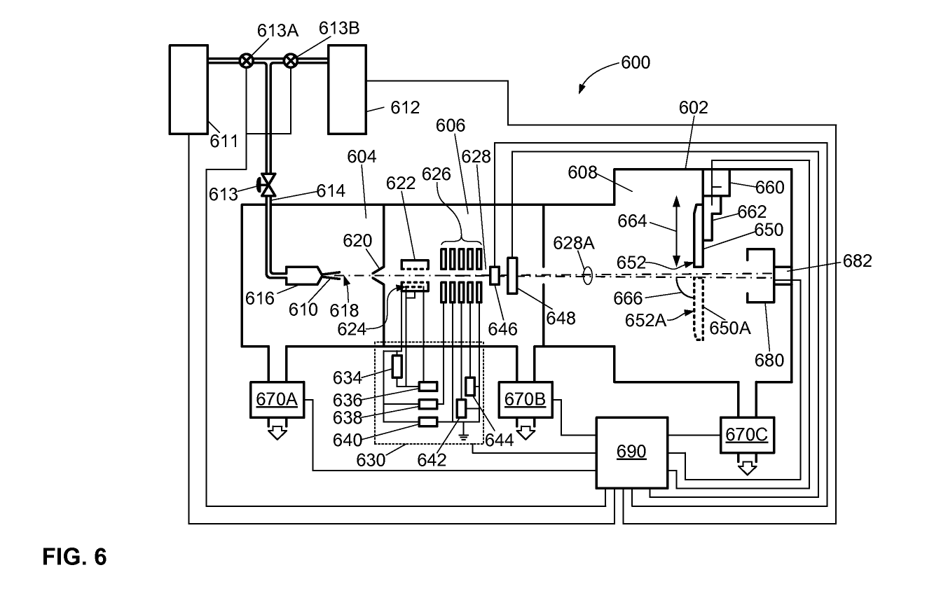

Referring now to FIG. 6, a GCIB processing system 600 for treating a substrate as described above is depicted according to an embodiment. The GCIB processing system 600 comprises a vacuum vessel 602, substrate holder 650, upon which a substrate 652 to be processed is affixed, and vacuum pumping systems 670A, 670B, and 670C. Substrate 652 can be a semiconductor substrate, a wafer, a flat panel display (FPD), a liquid crystal display (LCD), or any other workpiece. GCIB processing system 600 is configured to produce a GCIB for treating substrate 652.

Referring still to GCIB processing system 600 in FIG. 6, the vacuum vessel 602 comprises three communicating chambers, namely, a source chamber 604, an ionization/acceleration chamber 606, and a processing chamber 608 to provide a reduced-pressure enclosure. The three chambers are evacuated to suitable operating pressures by vacuum pumping systems 670A, 670B, and 670C, respectively. In the three communicating chambers 604, 606, 608, a gas cluster beam can be formed in the first chamber (source chamber 604), while a GCIB can be formed in the second chamber (ionization/acceleration chamber 606) wherein the gas cluster beam is ionized and accelerated. Then, in the third chamber (processing chamber 608), the accelerated GCIB may be utilized to treat substrate 652.

As shown in FIG. 6, GCIB processing system 600 can comprise one or more gas sources configured to introduce one or more gases or mixture of gases to vacuum vessel 602. For example, a first gas composition stored in a first gas source 611 is admitted under pressure through a first gas control valve 613A to a gas metering valve or valves 613. Additionally, for example, a second gas composition stored in a second gas source 612 is admitted under pressure through a second gas control valve 613B to the gas metering valve or valves 613. Further, for example, the first gas composition or second gas composition or both can include a condensable inert gas, carrier gas or dilution gas. For example, the inert gas, carrier gas or dilution gas can include a noble gas, i.e., He, Ne, Ar, Kr, Xe, or Rn.

Furthermore, the first gas source 611 and the second gas source 612 may be utilized either alone or in combination with one another to produce ionized clusters. The material composition can include the principal atomic or molecular species of the elements desired to be introduced to the material layer.

The high pressure, condensable gas comprising the first gas composition or the second gas composition or both is introduced through gas feed tube 614 into stagnation chamber 616 and is ejected into the substantially lower pressure vacuum through a properly shaped nozzle 610. As a result of the expansion of the high pressure, condensable gas from the stagnation chamber 616 to the lower pressure region of the source chamber 604, the gas velocity accelerates to supersonic speeds and gas cluster beam 618 emanates from nozzle 610.

The inherent cooling of the jet as static enthalpy is exchanged for kinetic energy, which results from the expansion in the jet, causes a portion of the gas jet to condense and form a gas cluster beam 618 having clusters, each consisting of from several to several thousand weakly bound atoms or molecules. A gas skimmer 620, positioned downstream from the exit of the nozzle 610 between the source chamber 604 and ionization/acceleration chamber 606, partially separates the gas molecules on the peripheral edge of the gas cluster beam 618, that may not have condensed into a cluster, from the gas molecules in the core of the gas cluster beam 618, that may have formed clusters. Among other reasons, this selection of a portion of gas cluster beam 618 can lead to a reduction in the pressure in the downstream regions where higher pressures may be detrimental (e.g., ionizer 622, and processing chamber 608). Furthermore, gas skimmer 620 defines an initial dimension for the gas cluster beam entering the ionization/acceleration chamber 606.

After the gas cluster beam 618 has been formed in the source chamber 604, the constituent gas clusters in gas cluster beam 618 are ionized by ionizer 622 to form GCIB 628. The ionizer 622 may include an electron impact ionizer that produces electrons from one or more filaments 624, which are accelerated and directed to collide with the gas clusters in the gas cluster beam 618 inside the ionization/acceleration chamber 606. Upon collisional impact with the gas cluster, electrons of sufficient energy eject electrons from molecules in the gas clusters to generate ionized molecules. The ionization of gas clusters can lead to a population of charged gas cluster ions, generally having a net positive charge.

As shown in FIG. 6, beam electronics 630 are utilized to ionize, extract, accelerate, and focus the GCIB 628. The beam electronics 630 include a filament power supply 636 that provides voltage V_{F} to heat the ionizer filament 624.

Additionally, the beam electronics 630 include a set of suitably biased high voltage electrodes 626 in the ionization/acceleration chamber 606 that extracts the cluster ions from the ionizer 622. The high voltage electrodes 626 then accelerate the extracted cluster ions to a desired energy and focus them to define GCIB 628. The kinetic energy of the cluster ions in GCIB 628 typically ranges from about 1000 electron volts (1 keV) to several tens of keV. For example, GCIB 628 can be accelerated to 1 to 100 keV.

As illustrated in FIG. 6, the beam electronics 630 further include an anode power supply 634 that provides voltage V_{A} to an anode of ionizer 622 for accelerating electrons emitted from filament 624 and causing the electrons to bombard the gas clusters in gas cluster beam 618, which produces cluster ions.

Additionally, as illustrated in FIG. 6, the beam electronics 630 include an extraction power supply 638 that provides voltage V_{EE} to bias at least one of the high voltage electrodes 626 to extract ions from the ionizing region of ionizer 622 and to form the GCIB 628. For example, extraction power supply 638 provides a voltage to a first electrode of the high voltage electrodes 626 that is less than or equal to the anode voltage of ionizer 622.

Furthermore, the beam electronics 630 can include an accelerator power supply 640 that provides voltage V_{ACC} to bias one of the high voltage electrodes 626 with respect to the ionizer 622 so as to result in a total GCIB acceleration energy equal to about V_{ACC} electron volts (eV). For example, accelerator power supply 640 provides a voltage to a second electrode of the high voltage electrodes 626 that is less than or equal to the anode voltage of ionizer 622 and the extraction voltage of the first electrode.

Further yet, the beam electronics 630 can include lens power supplies 642, 644 that may be provided to bias some of the high voltage electrodes 626 with potentials (e.g., V_{L1} and V_{L2}) to focus the GCIB 628. For example, lens power supply 642 can provide a voltage to a third electrode of the high voltage electrodes 626 that is less than or equal to the anode voltage of ionizer 622, the extraction voltage of the first electrode, and the accelerator voltage of the second electrode, and lens power supply 644 can provide a voltage to a fourth electrode of the high voltage electrodes 626 that is less than or equal to the anode voltage of ionizer 622, the extraction voltage of the first electrode, the accelerator voltage of the second electrode, and the first lens voltage of the third electrode.

Note that many variants on both the ionization and extraction schemes may be used. While the scheme described here is useful for purposes of instruction, another extraction scheme involves placing the ionizer and the first element of the extraction electrode(s) (or extraction optics) at V_{ACC}. This typically requires fiber optic programming of control voltages for the ionizer power supply, but creates a simpler overall optics train. The invention described herein is useful regardless of the details of the ionizer and extraction lens biasing.

A beam filter 646 in the ionization/acceleration chamber 606 downstream of the high voltage electrodes 626 can be utilized to eliminate monomers, or monomers and light cluster ions from the GCIB 628 to define a filtered process GCIB 628A that enters the processing chamber 608. In one embodiment, the beam filter 646 substantially reduces the number of clusters having 100 or less atoms or molecules or both. The beam filter may comprise a magnet assembly for imposing a magnetic field across the GCIB 628 to aid in the filtering process.

Referring still to FIG. 6, a beam gate 648 is disposed in the path of GCIB 628 in the ionization/acceleration chamber 606. Beam gate 648 has an open state in which the GCIB 628 is permitted to pass from the ionization/acceleration chamber 606 to the processing chamber 608 to define process GCIB 628A, and a closed state in which the GCIB 628 is blocked from entering the processing chamber 608. A control cable conducts control signals from control system 690 to beam gate 648. The control signals controllably switch beam gate 648 between the open or closed states.

A substrate 652, which may be a wafer or semiconductor wafer, a flat panel display (FPD), a liquid crystal display (LCD), or other substrate to be processed by GCIB processing, is disposed in the path of the process GCIB 628A in the processing chamber 608. Because most applications contemplate the processing of large substrates with spatially uniform results, a scanning system may be desirable to uniformly scan the process GCIB 628A across large areas to produce spatially homogeneous results.

An X-scan actuator 660 provides linear motion of the substrate holder 650 in the direction of X-scan motion (into and out of the plane of the paper). A Y-scan actuator 662 provides linear motion of the substrate holder 650 in the direction of Y-scan motion 664, which is typically orthogonal to the X-scan motion. The combination of X-scanning and Y-scanning motions translates the substrate 652, held by the substrate holder 650, in a raster-like scanning motion through process GCIB 628A to cause a uniform (or otherwise programmed) irradiation of a surface of the substrate 652 by the process GCIB 628A for processing of the substrate 652.

The substrate holder 650 disposes the substrate 652 at an angle with respect to the axis of the process GCIB 628A so that the process GCIB 628A has an angle of beam incidence 666 with respect to a substrate 652 surface. The angle of beam incidence 666 may be 90 degrees or some other angle, but is typically 90 degrees or near 90 degrees. During Y-scanning, the substrate 652 and the substrate holder 650 move from the shown position to the alternate position “A” indicated by the designators 652A and 650A, respectively. Notice that in moving between the two positions, the substrate 652 is scanned through the process GCIB 628A, and in both extreme positions, is moved completely out of the path of the process GCIB 628A (over-scanned). Though not shown explicitly in FIG. 6, similar scanning and over-scan is performed in the (typically) orthogonal X-scan motion direction (in and out of the plane of the paper).

A beam current sensor 680 may be disposed beyond the substrate holder 650 in the path of the process GCIB 628A so as to intercept a sample of the process GCIB 628A when the substrate holder 650 is scanned out of the path of the process GCIB 628A. The beam current sensor 680 is typically a faraday cup or the like, closed except for a beam-entry opening, and is typically affixed to the wall of the vacuum vessel 602 with an electrically insulating mount 682.

As shown in FIG. 6, control system 690 connects to the X-scan actuator 660 and the Y-scan actuator 662 through electrical cable and controls the X-scan actuator 660 and the Y-scan actuator 662 in order to place the substrate 652 into or out of the process GCIB 628A and to scan the substrate 652 uniformly relative to the process GCIB 628A to achieve desired processing of the substrate 652 by the process GCIB 628A. Control system 690 receives the sampled beam current collected by the beam current sensor 680 by way of an electrical cable and, thereby, monitors the GCIB and controls the GCIB dose received by the substrate 652 by removing the substrate 652 from the process GCIB 628A when a predetermined dose has been delivered.

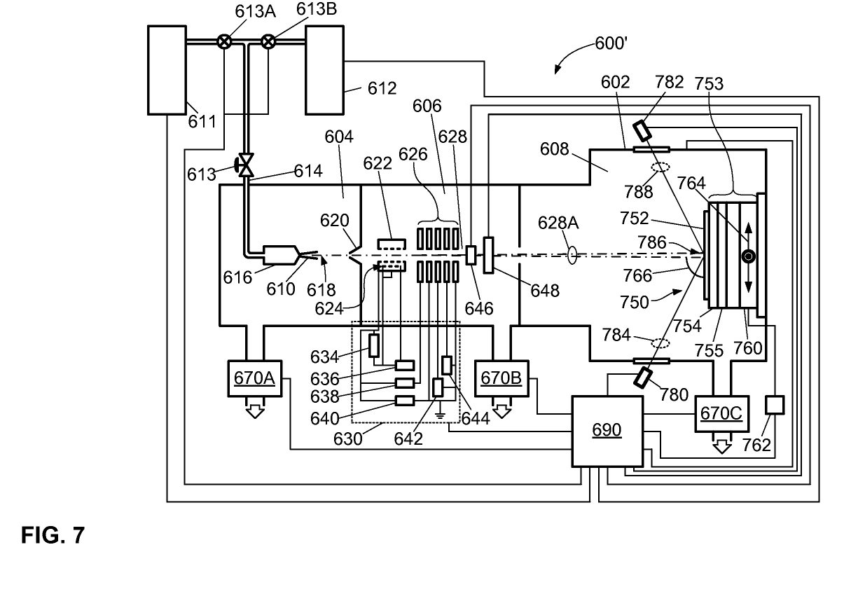

In the embodiment shown in FIG. 7, the GCIB processing system 600′ can be similar to the embodiment of FIG. 6 and further comprise a X-Y positioning table 753 operable to hold and move a substrate 752 in two axes, effectively scanning the substrate 752 relative to the process GCIB 128A. For example, the X-motion can include motion into and out of the plane of the paper, and the Y-motion can include motion along direction 764.

The process GCIB 628A impacts the substrate 752 at a projected impact region 786 on a surface of the substrate 752, and at an angle of beam incidence 766 with respect to the surface of substrate 752. By X-Y motion, the X-Y positioning table 753 can position each portion of a surface of the substrate 752 in the path of process GCIB 628A so that every region of the surface may be made to coincide with the projected impact region 786 for processing by the process GCIB 628A. An X-Y controller 762 provides electrical signals to the X-Y positioning table 753 through an electrical cable for controlling the position and velocity in each of X-axis and Y-axis directions. The X-Y controller 762 receives control signals from, and is operable by, control system 690 through an electrical cable. X-Y positioning table 753 moves by continuous motion or by stepwise motion according to conventional X-Y table positioning technology to position different regions of the substrate 752 within the projected impact region 786. In one embodiment, X-Y positioning table 753 is programmably operable by the control system 690 to scan, with programmable velocity, any portion of the substrate 752 through the projected impact region 786 for GCIB processing by the process GCIB 628A.

The substrate holding surface 754 of positioning table 753 is electrically conductive and is connected to a dosimetry processor operated by control system 690. An electrically insulating layer 755 of positioning table 753 isolates the substrate 752 and substrate holding surface 754 from the base portion 760 of the positioning table 753. Electrical charge induced in the substrate 752 by the impinging process GCIB 628A is conducted through substrate 752 and substrate holding surface 754, and a signal is coupled through the positioning table 753 to control system 690 for dosimetry measurement. Dosimetry measurement has integrating means for integrating the GCIB current to determine a GCIB processing dose. Under certain circumstances, a target-neutralizing source (not shown) of electrons, sometimes referred to as electron flood, may be used to neutralize the process GCIB 628A. In such case, a Faraday cup (not shown, but which may be similar to beam current sensor 680 in FIG. 6) may be used to assure accurate dosimetry despite the added source of electrical charge, the reason being that typical Faraday cups allow only the high energy positive ions to enter and be measured.

In operation, the control system 690 signals the opening of the beam gate 648 to irradiate the substrate 752 with the process GCIB 628A. The control system 690 monitors measurements of the GCIB current collected by the substrate 752 in order to compute the accumulated dose received by the substrate 752. When the dose received by the substrate 752 reaches a predetermined dose, the control system 690 closes the beam gate 648 and processing of the substrate 752 is complete. Based upon measurements of the GCIB dose received for a given area of the substrate 752, the control system 690 can adjust the scan velocity in order to achieve an appropriate beam dwell time to treat different regions of the substrate 752.

Alternatively, the process GCIB 628A may be scanned at a constant velocity in a fixed pattern across the surface of the substrate 752; however, the GCIB intensity is modulated (may be referred to as Z-axis modulation) to deliver an intentionally non-uniform dose to the sample. The GCIB intensity may be modulated in the GCIB processing system 600′ by any of a variety of methods, including varying the gas flow from a GCIB source supply; modulating the ionizer 622 by either varying a filament voltage V_{F} or varying an anode voltage V_{A}; modulating the lens focus by varying lens voltages V_{L1} and/or V_{L2}; or mechanically blocking a portion of the GCIB with a variable beam block, adjustable shutter, or variable aperture. The modulating variations may be continuous analog variations or may be time modulated switching or gating.

The processing chamber 608 may further include an in-situ metrology system. For example, the in-situ metrology system may include an optical diagnostic system having an optical transmitter 780 and optical receiver 782 configured to illuminate substrate 752 with an incident optical signal 784 and to receive a scattered optical signal 788 from substrate 752, respectively. The optical diagnostic system comprises optical windows to permit the passage of the incident optical signal 784 and the scattered optical signal 788 into and out of the processing chamber 608. Furthermore, the optical transmitter 780 and the optical receiver 782 may comprise transmitting and receiving optics, respectively. The optical transmitter 780 receives, and is responsive to, controlling electrical signals from the control system 690. The optical receiver 782 returns measurement signals to the control system 690.

The in-situ metrology system may comprise any instrument configured to monitor the progress of the GCIB processing. According to one embodiment, the in-situ metrology system may constitute an optical scatterometry system. The scatterometry system may include a scatterometer, incorporating beam profile ellipsometry (ellipsometer) and beam profile reflectometry (reflectometer), commercially available from Therma-Wave, Inc. (1250 Reliance Way, Fremont, Calif. 94539) or Nanometrics, Inc. (1550 Buckeye Drive, Milpitas, Calif. 95035).

For instance, the in-situ metrology system may include an integrated Optical Digital Profilometry (iODP) scatterometry module configured to measure process performance data resulting from the execution of a treatment process in the GCIB processing system 600′. The metrology system may, for example, measure or monitor metrology data resulting from the treatment process. The metrology data can, for example, be utilized to determine process performance data that characterizes the treatment process, such as a process rate, a relative process rate, a feature profile angle, a critical dimension, a feature thickness or depth, a feature shape, etc. For example, in a process for directionally depositing material on a substrate, process performance data can include a critical dimension (CD), such as a top, middle or bottom CD in a feature (i.e., via, line, etc.), a feature depth, a material thickness, a sidewall angle, a sidewall shape, a deposition rate, a relative deposition rate, a spatial distribution of any parameter thereof, a parameter to characterize the uniformity of any spatial distribution thereof, etc. Operating the X-Y positioning table 753 via control signals from control system 690, the in-situ metrology system can map one or more characteristics of the substrate 752.

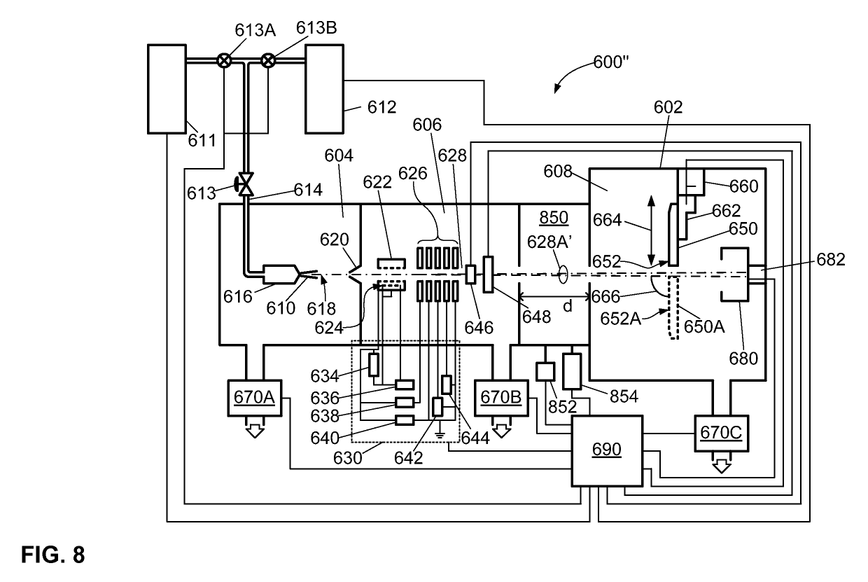

In the embodiment shown in FIG. 8, the GCIB processing system 600″ can be similar to the embodiment of FIG. 6 and further comprise a pressure cell chamber 850 positioned, for example, at or near an outlet region of the ionization/acceleration chamber 606. The pressure cell chamber 850 comprises an inert gas source 852 configured to supply a background gas to the pressure cell chamber 850 for elevating the pressure in the pressure cell chamber 850, and a pressure sensor 854 configured to measure the elevated pressure in the pressure cell chamber 850.

The pressure cell chamber 850 may be configured to modify the beam energy distribution of GCIB 628 to produce a modified processing GCIB 628A′. This modification of the beam energy distribution is achieved by directing GCIB 628 along a GCIB path through an increased pressure region within the pressure cell chamber 850 such that at least a portion of the GCIB traverses the increased pressure region. The extent of modification to the beam energy distribution may be characterized by a pressure-distance integral along the at least a portion of the GCIB path, where distance (or length of the pressure cell chamber 850) is indicated by path length (d). When the value of the pressure-distance integral is increased (either by increasing the pressure and/or the path length (d)), the beam energy distribution is broadened and the peak energy is decreased. When the value of the pressure-distance integral is decreased (either by decreasing the pressure and/or the path length (d)), the beam energy distribution is narrowed and the peak energy is increased. Further details for the design of a pressure cell may be determined from U.S. Pat. No. 7,060,989, entitled “Method and apparatus for improved processing with a gas-cluster ion beam”; the content of which is incorporated herein by reference in its entirety.

Control system 690 comprises a microprocessor, memory, and a digital I/O port capable of generating control voltages sufficient to communicate and activate inputs to GCIB processing system 600 (or 600′, 600″), as well as monitor outputs from GCIB processing system 600 (or 600′, 600″). Moreover, control system 690 can be coupled to and can exchange information with vacuum pumping systems 670A, 670B, and 670C, first gas source 611, second gas source 612, first gas control valve 613A, second gas control valve 613B, beam electronics 630, beam filter 646, beam gate 648, the X-scan actuator 660, the Y-scan actuator 662, and beam current sensor 680. For example, a program stored in the memory can be utilized to activate the inputs to the aforementioned components of GCIB processing system 600 according to a process recipe in order to perform a GCIB process on substrate 652.

However, the control system 690 may be implemented as a general purpose computer system that performs a portion or all of the microprocessor based processing steps of the invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The control system 690 can be used to configure any number of processing elements, as described above, and the control system 690 can collect, provide, process, store, and display data from processing elements. The control system 690 can include a number of applications, as well as a number of controllers, for controlling one or more of the processing elements. For example, control system 690 can include a graphic user interface (GUI) component (not shown) that can provide interfaces that enable a user to monitor and/or control one or more processing elements.

Control system 690 can be locally located relative to the GCIB processing system 600 (or 600′, 600″), or it can be remotely located relative to the GCIB processing system 600 (or 600′, 600″). For example, control system 690 can exchange data with GCIB processing system 600 using a direct connection, an intranet, and/or the internet. Control system 690 can be coupled to an intranet at, for example, a customer site (i.e., a device maker, etc.), or it can be coupled to an intranet at, for example, a vendor site (i.e., an equipment manufacturer). Alternatively or additionally, control system 690 can be coupled to the internet. Furthermore, another computer (i.e., controller, server, etc.) can access control system 690 to exchange data via a direct connection, an intranet, and/or the internet.

Substrate 652 (or 752) can be affixed to the substrate holder 650 (or substrate holder 750) via a clamping system (not shown), such as a mechanical clamping system or an electrical clamping system (e.g., an electrostatic clamping system). Furthermore, substrate holder 650 (or 750) can include a heating system (not shown) or a cooling system (not shown) that is configured to adjust and/or control the temperature of substrate holder 650 (or 750) and substrate 652 (or 752).

Vacuum pumping systems 670A, 670B, and 670C can include turbo-molecular vacuum pumps (TMP) capable of pumping speeds up to about 5000 liters per second (and greater) and a gate valve for throttling the chamber pressure. In conventional vacuum processing devices, a 6000 to 3000 liter per second TMP can be employed. TMPs are useful for low pressure processing, typically less than about 50 mTorr. Although not shown, it may be understood that pressure cell chamber 850 may also include a vacuum pumping system. Furthermore, a device for monitoring chamber pressure (not shown) can be coupled to the vacuum vessel 602 or any of the three vacuum chambers 604, 606, 608. The pressure-measuring device can be, for example, a capacitance manometer or ionization gauge.

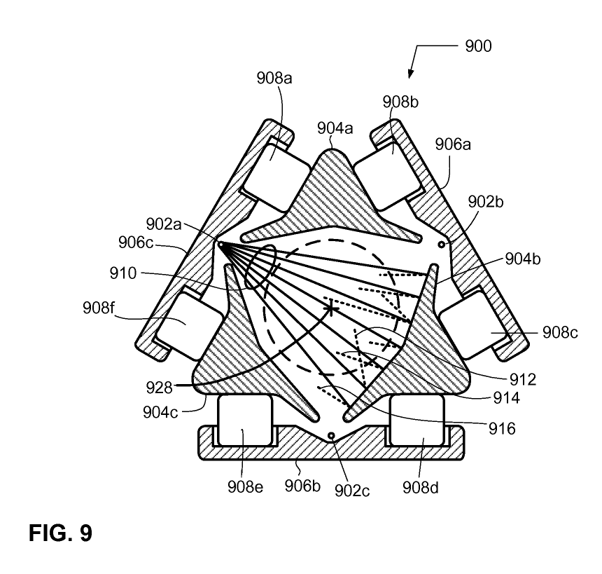

Referring now to FIG. 9, a section 900 of a gas cluster ionizer (622, FIGS. 6, 7 and 8) for ionizing a gas cluster jet (gas cluster beam 618, FIGS. 6, 7 and 8) is shown. The section 900 is normal to the axis of GCIB 928. For typical gas cluster sizes (2000 to 15000 atoms), clusters leaving the gas skimmer aperture (620, FIGS. 6, 7 and 8) and entering an ionizer (622, FIGS. 6, 7 and 8) will travel with a kinetic energy of about 130 to 1000 electron volts (eV). At these low energies, any departure from space charge neutrality within the ionizer 622 will result in a rapid dispersion of the jet with a significant loss of beam current. FIG. 9 illustrates a self-neutralizing ionizer. As with other ionizers, gas clusters are ionized by electron impact. In this design, thermo-electrons (seven examples indicated by 910) are emitted from multiple linear thermionic filaments 902a, 902b, and 902c (typically tungsten) and are extracted and focused by the action of suitable electric fields provided by electron-repeller electrodes 906a, 906b, and 906c and beam-forming electrodes 904a, 904b, and 904c. Thermo-electrons 910 pass through the gas cluster jet and the jet axis and then strike the opposite beam-forming electrode 904b to produce low energy secondary electrons (912, 914, and 916 indicated for examples).

Though (for simplicity) not shown, linear thermionic filaments 902b and 902c also produce thermo-electrons that subsequently produce low energy secondary electrons. All the secondary electrons help ensure that the ionized cluster jet remains space charge neutral by providing low energy electrons that can be attracted into the positively ionized gas cluster jet as required to maintain space charge neutrality. Beam-forming electrodes 904a, 904b, and 904c are biased positively with respect to linear thermionic filaments 902a, 902b, and 902c and electron-repeller electrodes 906a, 906b, and 906c are negatively biased with respect to linear thermionic filaments 902a, 902b, and 902c. Insulators 908a, 908b, 908c, 908d, 908e, and 908f electrically insulate and support electrodes 904a, 904b, 904c, 906a, 906b, and 906c. For example, this self-neutralizing ionizer is effective and achieves over 1000 micro Amps argon GCIBs.

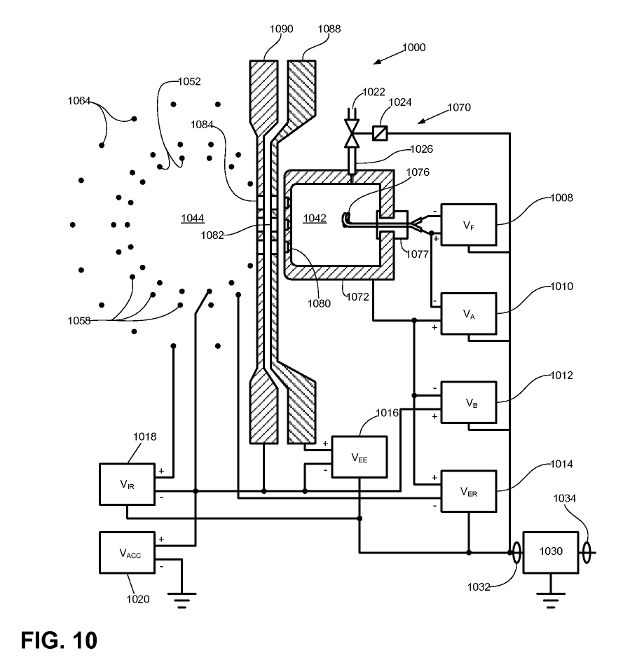

Alternatively, ionizers may use electron extraction from plasma to ionize clusters. The geometry of these ionizers is quite different from the three filament ionizer described above but the principles of operation and the ionizer control are very similar. Referring now to FIG. 10, a section 1000 of a gas cluster ionizer (622, FIGS. 6, 7 and 8) for ionizing a gas cluster jet (gas cluster beam 618, FIGS. 6, 7 and 8) is shown. The section 1000 is normal to the axis of GCIB 628. For typical gas cluster sizes (2000 to 15000 atoms), clusters leaving the gas skimmer aperture (620, FIGS. 6, 7 and 8) and entering an ionizer (622, FIGS. 6, 7 and 8) will travel with a kinetic energy of about 130 to 1000 electron volts (eV). At these low energies, any departure from space charge neutrality within the ionizer 622 will result in a rapid dispersion of the jet with a significant loss of beam current. FIG. 10 illustrates a self-neutralizing ionizer. As with other ionizers, gas clusters are ionized by electron impact.

The ionizer includes an array of thin rod anode electrodes 1052 that is supported and electrically connected by a support plate (not shown). The array of thin rod anode electrodes 1052 is substantially concentric with the axis of the gas cluster beam (e.g., gas cluster beam 618, FIGS. 6, 7 and 8). The ionizer also includes an array of thin rod electron-repeller rods 1058 that is supported and electrically connected by another support plate (not shown). The array of thin rod electron-repeller electrodes 1058 is substantially concentric with the axis of the gas cluster beam (e.g., gas cluster beam 618, FIGS. 6, 7 and 8). The ionizer further includes an array of thin rod ion-repeller rods 1064 that is supported and electrically connected by yet another support plate (not shown). The array of thin rod ion-repeller electrodes 1064 is substantially concentric with the axis of the gas cluster beam (e.g., gas cluster beam 618, FIGS. 6, 7 and 8).

Energetic electrons are supplied to a beam region 1044 from a plasma electron source 1070. The plasma electron source 1070 comprises a plasma chamber 1072 within which plasma is formed in plasma region 1042. The plasma electron source 1070 further comprises a thermionic filament 1076, a gas entry aperture 1026, and a plurality of extraction apertures 1080. The thermionic filament 1076 is insulated from the plasma chamber 1072 via insulator 1077. As an example, the thermionic filament 1076 may include a tungsten filament having one-and-a-half turns in a “pigtail” configuration.

The section 1000 of the gas cluster ionizer comprises an electron-acceleration electrode 1088 having plural apertures 1082. Additionally, the section 1000 comprises an electron-deceleration electrode 1090 having plural apertures 1084. The plural apertures 1082, the plural apertures 1084, and the plural extraction apertures 1080 are all aligned from the plasma region 1042 to the beam region 1044.

Plasma forming gas, such as a noble gas, is admitted to the plasma chamber 1072 through gas entry aperture 1026. An insulate gas feed line 1022 provides pressurized plasma forming gas to a remotely controllable gas valve 1024 that regulates the admission of plasma forming gas to the plasma chamber 1072.

A filament power supply 1008 provides filament voltage (V_{F}) for driving current through thermionic filament 1076 to stimulate thermo-electron emission. Filament power supply 1008 controllably provides about 140 to 200 A (amps) at 3 to 5 V (volts). An arc power supply 1010 controllably provides an arc voltage (V_{A}) to bias the plasma chamber 1072 positive with respect to the thermionic filament 1076. Arc power supply 1010 is typically operated at a fixed voltage, typically about 35 V, and provides means for accelerating the electrons within the plasma chamber 1072 for forming plasma. The filament current is controlled to regulate the arc current supplied by the arc power supply 1010. Arc power supply 1010 is capable of providing up to 5 A arc current to the plasma arc.

Electron deceleration electrode 1090 is biased positively with respect to the plasma chamber 1072 by electron bias power supply 1012. Electron bias power supply 1012 provides bias voltage (V_{B}) that is controllably adjustable over the range of from 30 to 400 V. Electron acceleration electrode 1088 is biased positively with respect to electron deceleration electrode 1090 by electron extraction power supply 1016. Electron extraction power supply 1016 provides electron extraction voltage (V_{EE}) that is controllable in the range from 20 to 250 V. An acceleration power supply 1020 supplies acceleration voltage (V_{ACC}) to bias the array of thin rod anode electrodes 1052 and electron deceleration electrode 1090 positive with respect to earth ground. V_{ACC} is the acceleration potential for gas cluster ions produced by the gas cluster ionizer shown in section 1000 and is controllable and adjustable in the range from 1 to 100 kV. An electron repeller power supply 1014 provides electron repeller bias voltage (V_{ER}) for biasing the array of thin rod electron-repeller electrodes 1058 negative with respect to V_{ACC}. V_{ER} is controllable in the range of from 50 to 100 V. An ion repeller power supply 1018 provides ion repeller bias voltage (V_{IR}) to bias the array of thin rod ion-repeller electrodes 1064 positive with respect to V_{ACC}. V_{IR} is controllable in the range of from 50 to 150 V.

A fiber optics controller 1030 receives electrical control signals on cable 1034 and converts them to optical signals on control link 1032 to control components operating at high potentials using signals from a grounded control system. The fiber optics control link 1032 conveys control signals to remotely controllable gas valve 1024, filament power supply 1008, arc power supply 1010, electron bias power supply 1012, electron repeller power supply 1014, electron extraction power supply 1016, and ion repeller power supply 1018.

For example, the ionizer design may be similar to the ionizer described in U.S. Pat. No. 7,173,252, entitled “Ionizer and method for gas-cluster ion-beam formation”; the content of which is incorporated herein by reference in its entirety.

The gas cluster ionizer (122, FIGS. 6, 7 and 8) may be configured to modify the beam energy distribution of GCIB 128 by altering the charge state of the GCIB 128. For example, the charge state may be modified by adjusting an electron flux, an electron energy, or an electron energy distribution for electrons utilized in electron collision-induced ionization of gas clusters.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

1. A method of patterning an insulation layer, comprising:
preparing a feature pattern in an insulation layer using at least one hard mask layer formed on a flat field surface of said insulation layer, said insulation layer comprises a low-k material having a dielectric constant less than the dielectric constant of SiO₂;
removing said at least one hard mask layer to expose said flat field surface of said insulation layer; and
following said removing, depositing a passivation layer on said flat field surface to protect said insulation layer using gas cluster ion beam (GCIB) irradiation of said insulation layer, wherein said GCIB irradiation is configured to grow or deposit said passivation layer on said flat field surface.

2. The method of claim 1, wherein said passivation layer is deposited to a thickness up to about 25 nm (nanometers).

3. The method of claim 1, wherein said passivation layer is deposited to a thickness up to about 10 nm.

4. The method of claim 1, wherein said passivation layer is deposited to a thickness ranging from about 2 nm to about 5 nm.

5. The method of claim 1, further comprising:
extending said passivation layer from said flat field surface to at least a portion of a sidewall surface of said feature pattern in said insulation layer using said GCIB irradiation, wherein a thickness of said passivation layer on said portion of said sidewall surface is equal to or less than a thickness of said passivation layer on said flat field surface, and wherein said passivation layer is continuous from said flat field surface to said portion of said sidewall surface.

6. The method of claim 1, wherein said GCIB irradiation comprises:
establishing said GCIB;
selecting a beam energy, a beam energy distribution, a beam focus, and a beam dose to achieve a desired thickness of said passivation layer formed during said GCIB irradiation of said insulation layer;
accelerating said GCIB to achieve said beam energy;
focusing said GCIB to achieve said beam focus; and
exposing said insulation layer to said accelerated GCIB according to said beam dose,
wherein said beam energy ranges from about 1 keV to about 60 keV, and said beam dose ranges from about 1×10¹² clusters per cm² to about 1×10¹⁴ clusters per cm².

7. The method of claim 1, wherein said removing said at least one hard mask layer comprises using a polishing process, a planarization process, an etching process, a cleaning process, a dry etching process, a wet etching process, a dry plasma etching process, a dry non-plasma etching process, or a GCIB etching process, or any combination of two or more thereof.

8. The method of claim 1, further comprising:
cleaning exposed surfaces of said insulation layer including said flat field surface to remove moisture, etch process residue, and/or ash process residue, wherein said cleaning proceeds following said removing and preceding said depositing said passivation layer.

9. The method of claim 1, further comprising:
treating exposed surfaces of said insulation layer including said flat field surface to repair surface layers of said insulation layer, wherein said treating proceeds following said removing and preceding said depositing said passivation layer.

10. The method of claim 9, wherein said treating comprises replenishing carbon depleted sites with carbon-containing material.

11. The method of claim 9, wherein said treating comprises exposing said insulation layer to a second GCIB irradiation.

12. The method of claim 1, further comprising:
forming a metal barrier layer on said passivation layer and said insulation layer conformal with said feature pattern;
filling said feature pattern with metal; and
polishing said metal to produce an upper metal surface coplanar with said flat field surface of said insulation layer or at least a portion of said passivation layer on said flat field surface of said insulation layer.

13. The method of claim 1, wherein said insulation layer comprises a porous low-k material.

14. The method of claim 1, wherein said insulation layer comprises a film including silicon, carbon, oxygen, and optionally hydrogen.

15. The method of claim 1, wherein said at least one hard mask layer comprises at least one layer containing Si, or at least one layer containing a metal.

16. The method of claim 1, wherein said preparing said feature pattern is incorporated within a damascene integration scheme, a dual damascene integration scheme, a trench-first-metal-hard-mask (TFMHM) integration scheme, or a via-first-trench-last (VFTL) integration scheme.

17. The method of claim 1, wherein said feature pattern comprises a trench, or a via, or a combination of a trench and a via.

18. The method of claim 1, wherein said passivation layer contains one or more elements selected from the group consisting of Si, C, N, O, and H.

19. The method of claim 1, further comprising:
irradiating said insulation layer with another gas cluster ion beam (GCIB) preceding said forming said passivation layer or following said growing or depositing said passivation layer.

20. The method of claim 19, wherein said another GCIB comprises at least one element selected from the group consisting of He, Ne, Ar, Xe, Kr, B, C, Si, Ge, N, P, As, O, S, F, Cl, and Br.

21. The method of claim 1, wherein said GCIB contains Si, and said GCIB irradiation is configured to deposit said passivation layer containing Si on said flat field surface.
